(19) United States
(12) Patent Application Publication
(10) Pub. No.: US 2025/0159873 A1
(43) Pub. Date: May 15, 2025

(54) SEMICONDUCTOR MEMORY DEVICE INCLUDING VERTICAL CELL TRANSISTORS

(71) Applicant: SAMSUNG ELECTRONICS CO., LTD., SUWON-SI, GYEONGGI-DO (KR)

(72) Inventors: YOUNG SEOK PARK, Suwon-si, Gyeonggi-do (KR); HYUN-CHUL YOON, Suwon-si, Gyeonggi-do (KR); ChangSik YOO, Suwon-si, Gyeonggi-do (KR); JEONGDON IHM, Suwon-si, Gyeonggi-do (KR)

(21) Appl. No.: 18/747,036

(22) Filed: Jun. 18, 2024

(30) Foreign Application Priority Data
Nov. 15, 2023 (KR) 10-2023-0158533

(51) Int. Cl. H10B 12/00

(52) U.S. Cl. CPC H10B 12/50; H10B 12/315

(57) ABSTRACT

A semiconductor memory device includes a peripheral circuit structure, and a cell array structure provided thereon and including a plurality of cell array regions and an upper peripheral region provided between a plurality of cell array regions. A cell array structure includes vertical cell transistors, first vertical peripheral transistors, and second vertical peripheral transistors. Each of vertical cell transistors, a first vertical peripheral transistors, and a second vertical peripheral transistors has a channel extending along a third direction parallel to an arrangement direction of a peripheral circuit structure and a cell array structure. Vertical cell transistors are disposed in a cell array region and have a first polarity. First vertical peripheral transistors are disposed in an upper peripheral region and have a first polarity. Second vertical peripheral transistors are disposed in an upper peripheral region and have a second polarity different from a first polarity.

### CROSS-REFERENCE TO RELATED APPLICATIONS

This application claims priority under 35 U.S.C. § 119 to Korean Patent Application No. 10-2023-0158533, filed on Nov. 15, 2023, in the Korean Intellectual Property Office, the disclosure of which is incorporated by reference herein in its entireties.

### TECHNICAL FIELD

The present disclosure relates to semiconductor memory devices and, more specifically, to semiconductor memory devices including vertical cell transistors.

### DISCUSSION OF THE RELATED ART

Research is underway to reduce the size and increase the performance of the elements that make up semiconductor devices. For example, in the field of dynamic random access memory (DRAM), research is underway to reliably and stably form elements of reduced size. However, as the size of components shrinks, it becomes increasingly difficult to implement transistors with desired performance.

### SUMMARY

A semiconductor memory device includes a peripheral circuit structure and a cell array structure disposed on the peripheral circuit structure and including a plurality of cell array regions and an upper peripheral region disposed between the plurality of cell array regions. The cell array structure includes vertical cell transistors, first vertical peripheral transistors, and second vertical peripheral transistors. Each of the vertical cell transistors, the first vertical peripheral transistors, and the second vertical peripheral transistors has a channel extending along a third direction parallel to an arrangement direction of the peripheral circuit structure and the cell array structure. The vertical cell transistors are disposed in the cell array region and have a first polarity. The first vertical peripheral transistors are disposed in the upper peripheral region and have the first polarity. The second vertical peripheral transistors are disposed in the upper peripheral region and have a second polarity different from the first polarity.

A semiconductor memory device includes a peripheral circuit structure and a cell array structure disposed on the peripheral circuit structure. The peripheral circuit structure includes horizontal peripheral transistors having a channel extending along a first direction intersecting an arrangement direction of the peripheral circuit structure and the cell array structure. The cell array structure includes capacitors, vertical cell transistors, first vertical peripheral transistors, and second vertical peripheral transistors. The capacitors are electrically connected to the vertical cell transistors. Each of the vertical cell transistors, the first vertical peripheral transistors, and the second vertical peripheral transistors has a channel extending along a third direction parallel to an arrangement direction of the peripheral circuit structure and the cell array structure. The first vertical peripheral transistors and the second vertical peripheral transistors have a first polarity and a second polarity different from the first polarity, respectively.

A semiconductor memory device includes a substrate including a plurality of cell array regions and an upper peripheral region disposed between the plurality of cell array regions. First conductive lines extend along a first direction on the substrate and are arranged along a second direction intersecting the first direction. Vertical cell transistors, first vertical peripheral transistors, and second vertical peripheral transistors are provided on the first conductive lines. Capacitors are provided on each of the vertical cell transistors. Each of the vertical cell transistors, the first vertical peripheral transistors, and the second vertical peripheral transistors has a channel extending along a third direction perpendicular to the top surface of the substrate. The vertical cell transistors are NMOS transistors disposed in the cell array region. The first vertical peripheral transistors are NMOS transistors disposed in the upper peripheral region. The second vertical peripheral transistors are PMOS transistors disposed in the upper peripheral region.

### BRIEF DESCRIPTION OF DRAWINGS

The above and other aspects, features, and elements of certain embodiments of the present disclosure will be more apparent from the following description taken in conjunction with the accompanying drawings, in which:

FIG. 1 is a block diagram illustrating a semiconductor memory device according to example embodiments;

FIG. 2 is a schematic perspective view illustrating a semiconductor memory device according to example embodiments;

FIG. 3 is a plan view illustrating a cell array structure of FIG. 2;

FIG. 4A is a plan view illustrating a peripheral circuit structure of FIG. 2 and, in particular, element AA of FIG. 3 and FIG. 4B is a plan view illustrating a peripheral circuit structure of FIG. 2 and, in particular, element BB of FIG. 3;

FIG. 5A is a plan view of a cell array structure according to example embodiments;

FIG. 5B is a cross-sectional view taken along lines A-A′ and B-B′ of FIG. 5A;

FIG. 5C is a cross-sectional view taken along lines C-C′ and D-D′ of FIG. 5A;

FIG. 6A illustrates an inverter circuit including the first vertical peripheral transistor and the second vertical peripheral transistor of FIGS. 5A to 5C;

FIG. 6B illustrates a latch circuit including the first vertical peripheral transistor and the second vertical peripheral transistor of FIGS. 5A to 5C;

FIG. 7 is a flowchart illustrating a method of manufacturing a cell array structure according to an embodiment;

FIGS. 8A, 9A, 10A, 11A, 12A, and 13A are plan views illustrating a manufacturing method of the arrangement shown in FIG. 7;

FIGS. 8B, 8C, 9B, 9C, 10B, 10C, 11B, 11C, 12B, 12C, 13B, and 13C are cross-sectional views corresponding to lines A-A′, B-B′, C-C′, and D-D′ in FIGS. 9A, 10A, 11A, 12A, and 13A illustrating a manufacturing method of the arrangement shown in FIG. 7; and

FIG. 14 is a cross-sectional view illustrating a semiconductor memory device according to example embodiments.

### DETAILED DESCRIPTION

Hereinafter, examples for carrying out the present invention will be clearly and specifically described so that one having ordinary skill in the technical field of the present invention may readily practice the invention.

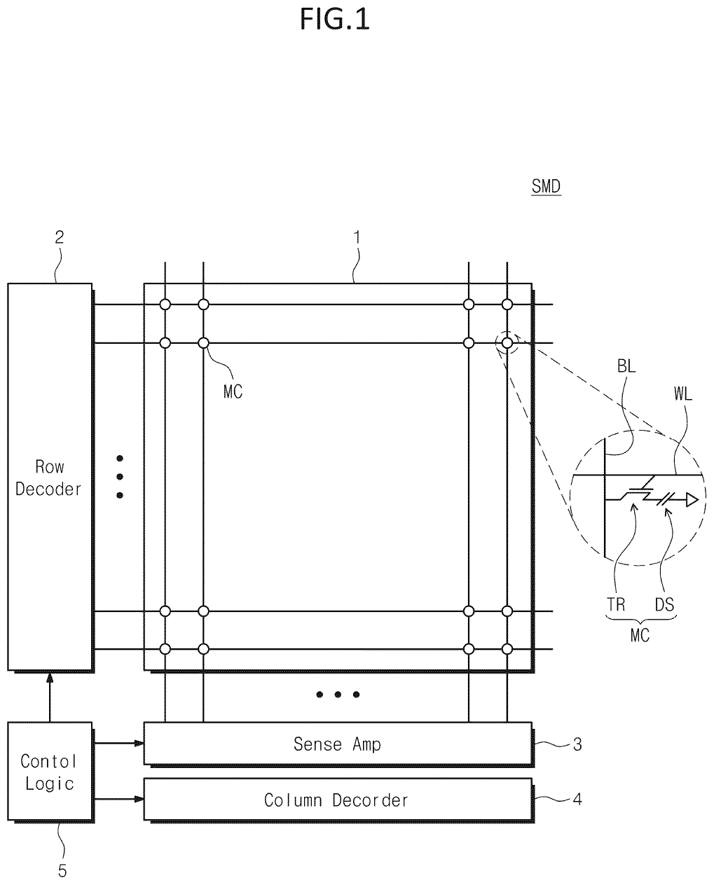

FIG. 1 is a block diagram illustrating a semiconductor memory device according to example embodiments.

Referring to FIG. 1, a semiconductor memory device SMD may include a memory cell array 1, a row decoder 2, a sense amplifier 3, a column decoder 4, and a control logic circuit 5. The memory cell array 1 may include a plurality of memory cells MC arranged two-dimensionally (e.g., alongside one another) or three-dimensionally (e.g., stacked upon each other). Each of the memory cells MC may be connected between a word line WL and a bit line 102 that intersect each other.

Each memory cell MC includes a selection element TR and a data storage element DS, and the selection element TR and the data storage element DS may be electrically connected in series. The selection device TR may be controlled by a signal transmitted through the word line WL. For example, the selection element TR may be a field effect transistor (FET). The data storage device DS may be connected to the bit line 102 through the selection device TR. For example, the data storage element DS may include a capacitor, a magnetic tunnel junction pattern, or a variable resistor. The gate electrode of the selection element TR may be connected to the word line WL, and the drain/source terminals may be connected to the bit line 102 and the data storage element DS, respectively.

The row decoder 2 may decode an externally input address and select one of the word lines WL of the memory cell array 1. The address decoded in the row decoder 2 may be provided to a row driver. The row driver may provide a predetermined voltage to the selected word line WL and the unselected word lines WL, respectively, in response to control of the control circuits.

The sense amplifier 3 may detect and amplify the voltage difference between the bit line 102 selected according to the address decoded from the column decoder 4 and the reference bit line and output the amplified voltage difference.

The column decoder 4 may provide a data transmission path between the sense amplifier 3 and an external device (e.g., a memory controller). The column decoder 4 may decode an externally input address and select one of the bit lines 102.

The control logic circuit 5 may generate control signals that control writing or reading operations of data to the memory cell array 1.

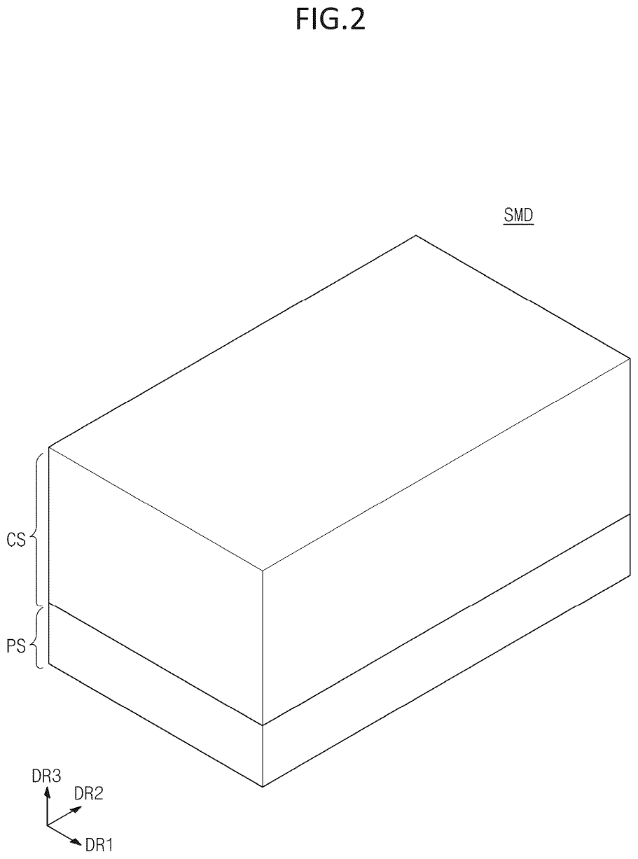

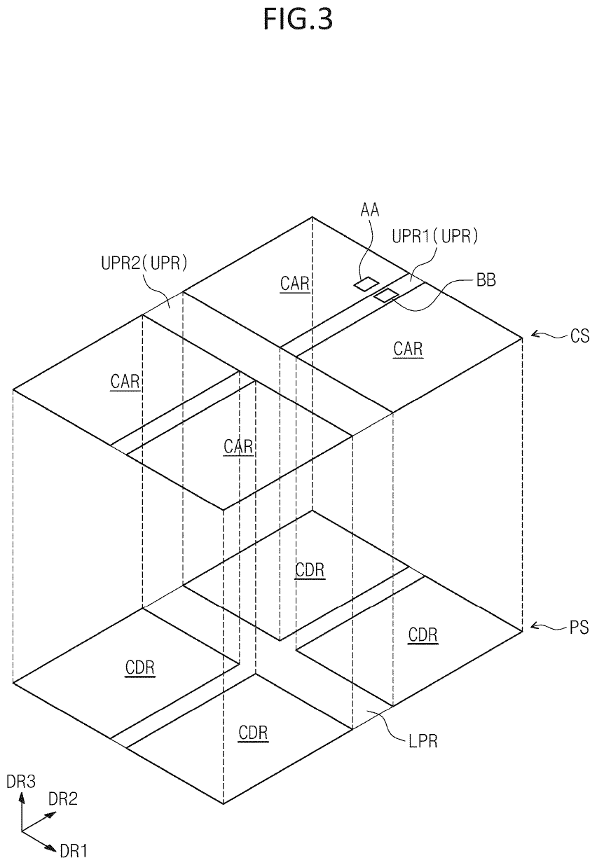

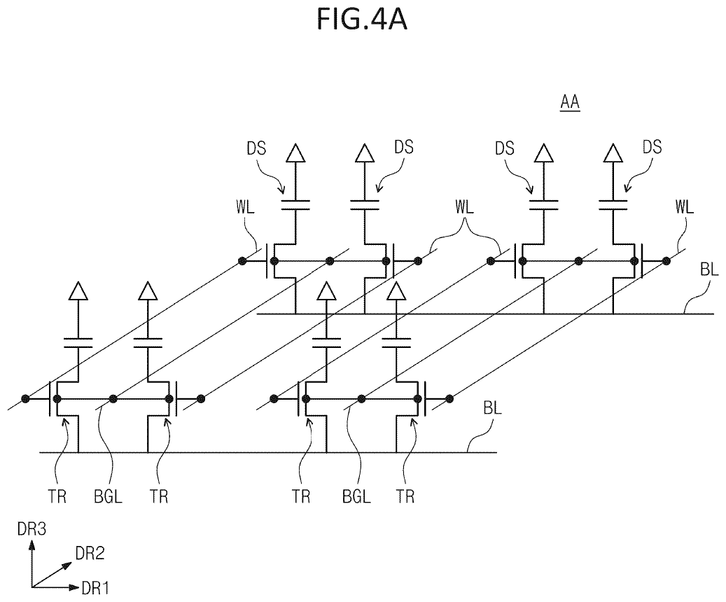

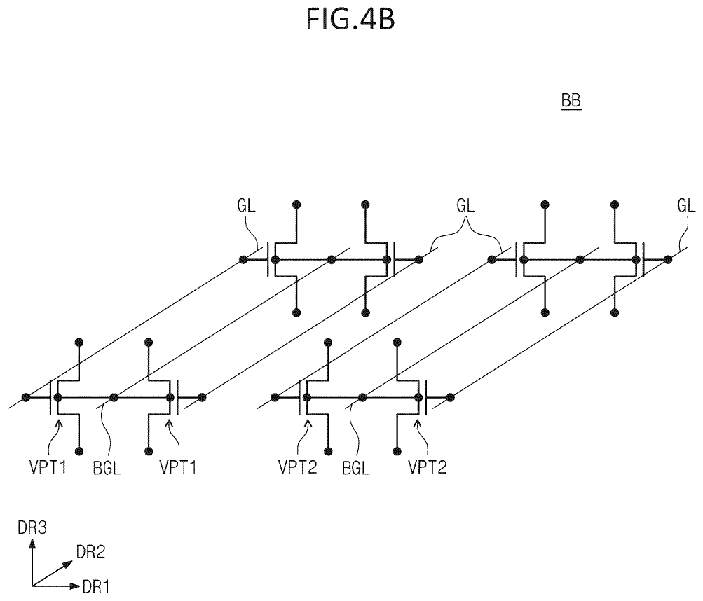

FIG. 2 is a schematic perspective view of a semiconductor memory device according to example embodiments. FIG. 3 is a plan view illustrating a cell array structure of FIG. 2. FIG. 4A is a plan view illustrating a peripheral circuit structure of FIG. 2 and, in particular, element AA of FIG. 3 and FIG. 4B is a plan view illustrating a peripheral circuit structure of FIG. 2 and, in particular, element BB of FIG. 3.

Referring to FIGS. 2 to 4, the semiconductor memory device SMD may include a peripheral circuit structure PS and a cell array structure CS on the peripheral circuit structure PS. The peripheral circuit structure PS and the cell array structure CS may be arranged along the third direction DR3. For example, the peripheral circuit structure PS and the cell array structure CS may be bonded to each other by “Cu-copper bonding,” which is a technique for creating a strong electrical connection between two pieces of copper (Cu).

The cell array structure CS may include cell array regions CAR and an upper peripheral region UPR. The cell array regions CAR may be arranged along the first direction DR1 and the second direction DR2. Although the cell array regions CAR are shown as being arranged in a 2×2 shape, this is illustrative. The arrangement form of the cell array regions CAR may be determined as needed. The upper peripheral region UPR may be provided between the cell array regions CAR. For example, the upper peripheral region UPR may include a first upper peripheral regions UPR1 (UPR) provided between the cell array regions CAR arranged along the first direction DR1. For example, the upper peripheral region UPR may include a second upper peripheral region UPR2 (UPR) provided between the cell array regions CAR arranged along the second direction DR2. The first upper peripheral regions UPR1 (UPR) may extend along the second direction DR2. The first upper peripheral regions UPR1 (UPR) may be spaced apart from each other by the second upper peripheral region UPR. The second upper peripheral region UPR may extend along the first direction DR1.

The cell array region CAR may include the bit lines BL in FIG. 1, the word lines WL in FIG. 1, the memory cells MC in FIG. 1, and back gate lines BGL. The bit lines 102 may extend along the first direction DR1. The bit lines 102 may extend along the second direction DR2 that intersects the first direction DR1. The word lines WL may extend along the second direction DR2. The word lines WL may be arranged along the first direction DR1. The memory cells MC may be arranged two-dimensionally or three-dimensionally on a plane extending in the first and second directions DR1 and DR2. For example, the memory cells MC may be arranged along the first direction DR1 and the second direction DR2. Each of the memory cells MC may include the selection element TR in FIG. 1 and the data storage element DS in FIG. 1. In one embodiment, the selection element TR may be a vertical channel transistor (VCT). The vertical channel transistor may refer to a structure in which the channel length extends in the vertical direction (i.e., the third direction DR3). In one embodiment, the data storage device DS may include a capacitor.

The back gate lines BGL may extend along the second direction DR2. Each of the back gate lines BGL may be provided between selection elements TR immediately adjacent to each other along the first direction DR1. The back gate lines BGL may be spaced apart from the word lines WL along the first direction DR1 with the selection elements TR interposed therebetween. In one embodiment, the back gate lines BGL may be located at substantially the same height as the word lines WL. The back gate lines BGL may increase the threshold voltage of the selection elements TR. Accordingly, even if the selection elements TR have a small size, the threshold voltage may be reduced and the leakage current characteristics may be prevented from being deteriorated.

The upper peripheral region UPR may include at least some of the peripheral circuits. Peripheral circuits provided in the upper peripheral region UPR may include control logic circuits 5 in FIG. 1. For example, peripheral circuits provided in the upper peripheral region UPR may include a fuse box circuit, a mode resistor setting (MRS) circuit, a DC circuit, and other option-related circuits. Peripheral circuits provided in the upper peripheral region UPR may be implemented using, for example, an inverter circuit or a latch circuit. The upper peripheral region UPR may include first vertical peripheral transistors VPT1, second vertical peripheral transistors VPT2, peripheral gate lines GL, and back gate lines BGL. The first vertical peripheral transistors VPT1 and the second vertical peripheral transistors VPT2 may be vertical channel transistors. The first vertical peripheral transistors VPT1 may have a first polarity. The second vertical peripheral transistors VPT2 may have a second polarity different from the first polarity. When the first vertical peripheral transistors VPT1 are NMOS transistors, the second vertical peripheral transistors VPT2 may be PMOS transistors. When the first vertical peripheral transistors VPT1 are PMOS transistors, the second vertical peripheral transistors VPT2 may be NMOS transistors. The first vertical peripheral transistors VPT1 and the second vertical peripheral transistors VPT2 may be used to implement first peripheral circuits disposed in the upper peripheral region UPR. For example, the first vertical peripheral transistors VPT1 and the second vertical peripheral transistors VPT2 may be used to implement an inverter circuit, a latch circuit, etc. in the upper peripheral region UPR. The first vertical peripheral transistors VPT1 and the second vertical peripheral transistors VPT2 may be provided in the first upper peripheral region UPR and/or the second upper peripheral region UPR.

The peripheral gate lines GL may extend along the second direction DR2. The peripheral gate lines GL may be arranged along the first direction DR1. The peripheral gate lines GL may transmit gate signals that control the first vertical peripheral transistors VPT1 and the second vertical peripheral transistors VPT2. In example embodiments, the peripheral gate lines GL may be gate electrodes of the first vertical peripheral transistors VPT1 and the second vertical peripheral transistors VPT2.

The back gate lines BGL may extend along the second direction DR2. Each of the back gate lines BGL may be provided between first vertical peripheral transistors VPT1 that are immediately adjacent to each other along the first direction DR1. Each of the back gate lines BGL may be provided between the second vertical peripheral transistors VPT2 that are immediately adjacent to each other along the first direction DR1. The back gate lines BGL may be spaced apart from the peripheral gate lines GL in the first direction DR1 with the first vertical peripheral transistors VPT1 or the second vertical peripheral transistors VPT2 interposed therebetween. In one embodiment, the back gate lines BGL may be located at substantially the same height as the peripheral gate lines GL. The back gate lines BGL may increase the threshold voltage of the first vertical peripheral transistors VPT1 and the second vertical peripheral transistors VPT2. Accordingly, even if the first vertical peripheral transistors VPT1 and the second vertical peripheral transistors VPT2 have minute sizes, the threshold voltage may be reduced, thereby preventing leakage current characteristics from being deteriorated.

The peripheral circuit structure PS may include a cell driving region CDR and a lower peripheral region LPR. The cell driving regions CDR may be arranged along the first direction DR1 and the second direction DR2. As an embodiment, the cell driving regions CDRs are shown arranged in a 2×2 shape. The arrangement form of the cell driving regions CDR may be determined as needed. The cell driving regions CDR may at least partially overlap the cell array regions CAR along the third direction DR3. Cell driving regions CDR may include other portions of peripheral circuits. Peripheral circuits provided in the cell driving regions CDR may be configured to control memory cells MC in FIG. 1 provided in the cell array regions CAR. For example, the cell driving regions CDR may include the row decoder 2 in FIG. 1, the sense amplifier 3 in FIG. 1, and the column decoder 4 in FIG. 1.

The lower peripheral region LPR may include another portion of the peripheral circuits. In one embodiment, the lower peripheral region LPR and the cell driving regions CDR may include planar transistors. In example embodiments, horizontal conductive lines and vertical conductive lines may be disposed between the memory cells MC in FIG. 1 provided in the cell array structure CS and peripheral circuits to provide the required electrical connection. In example embodiments, horizontal conductive lines and vertical conductive lines may be disposed between memory cells (MC in FIG. 1) provided in the cell array structure CS and peripheral circuits provided in the peripheral circuit structure PS. Horizontal conductive lines and vertical conductive lines may provide the required electrical connection.

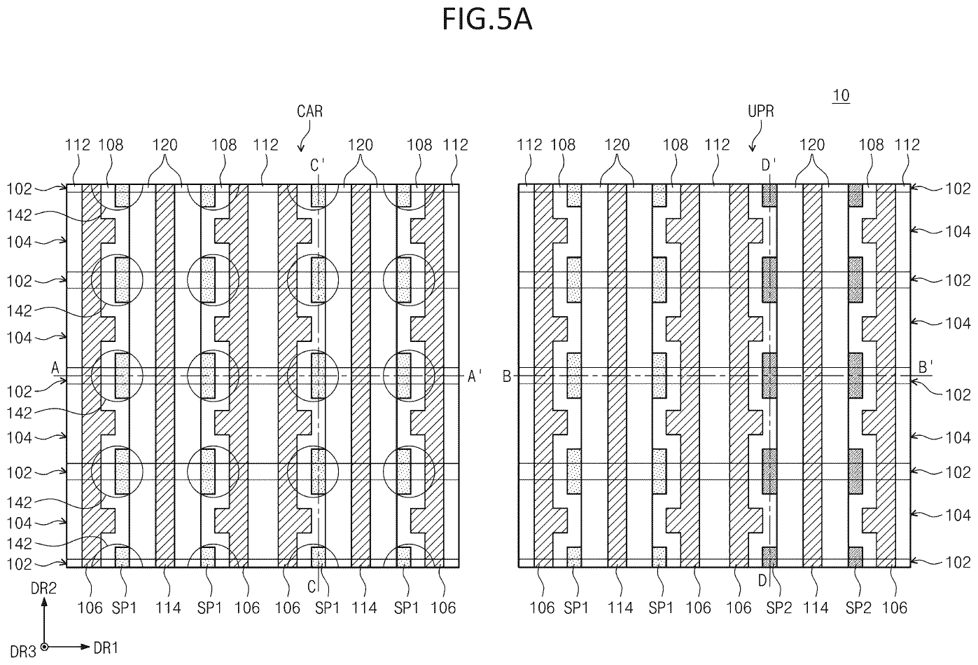

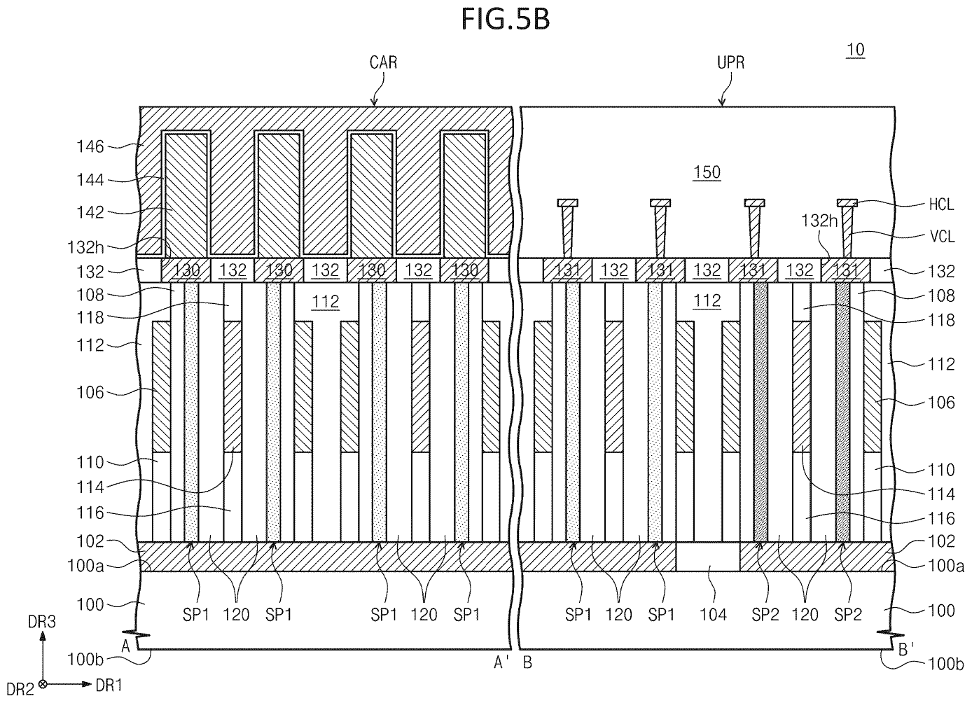

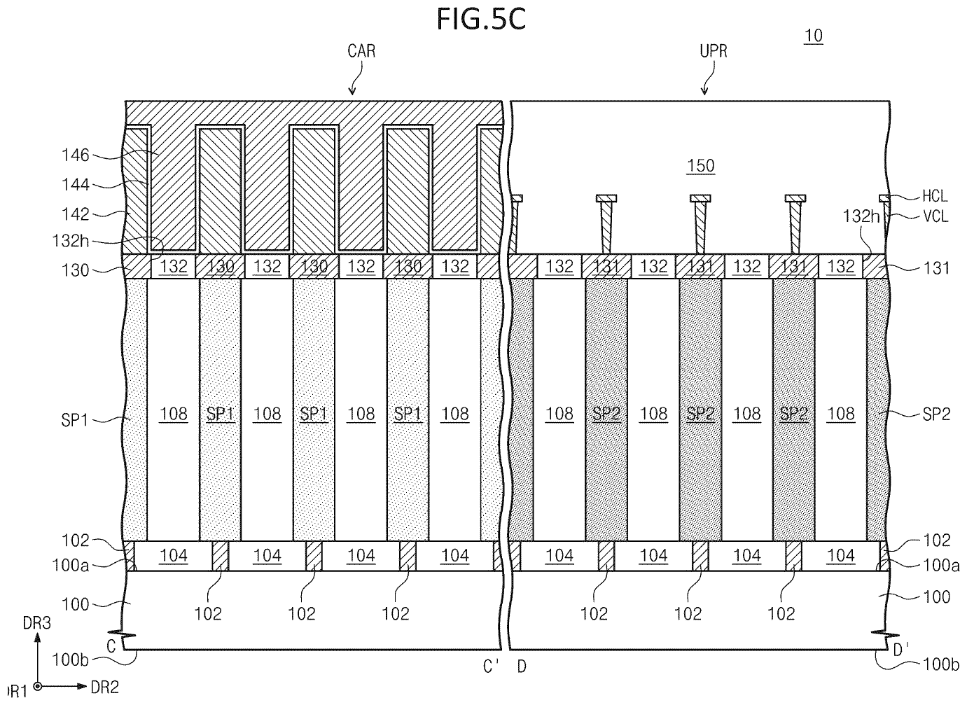

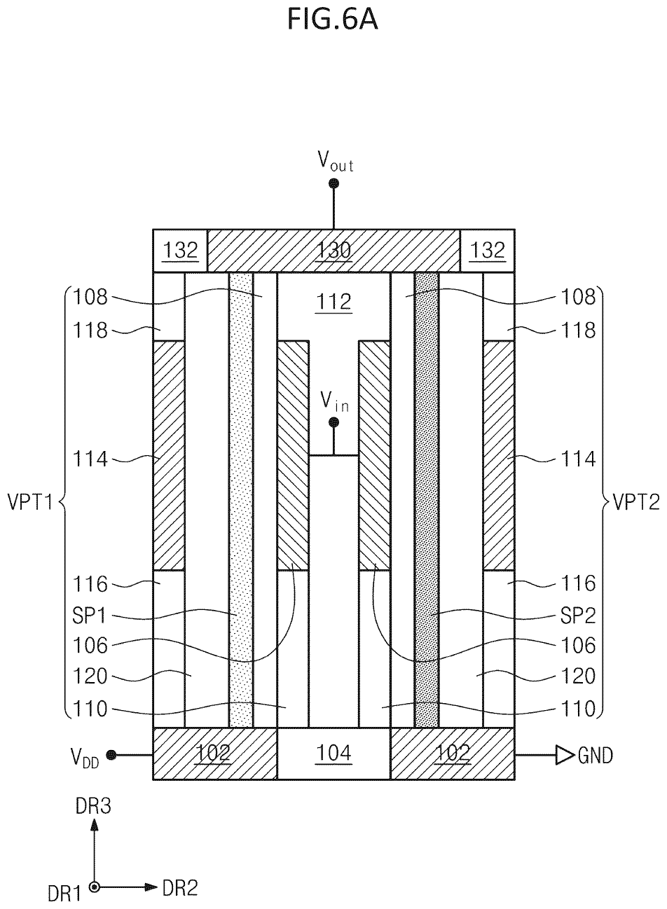

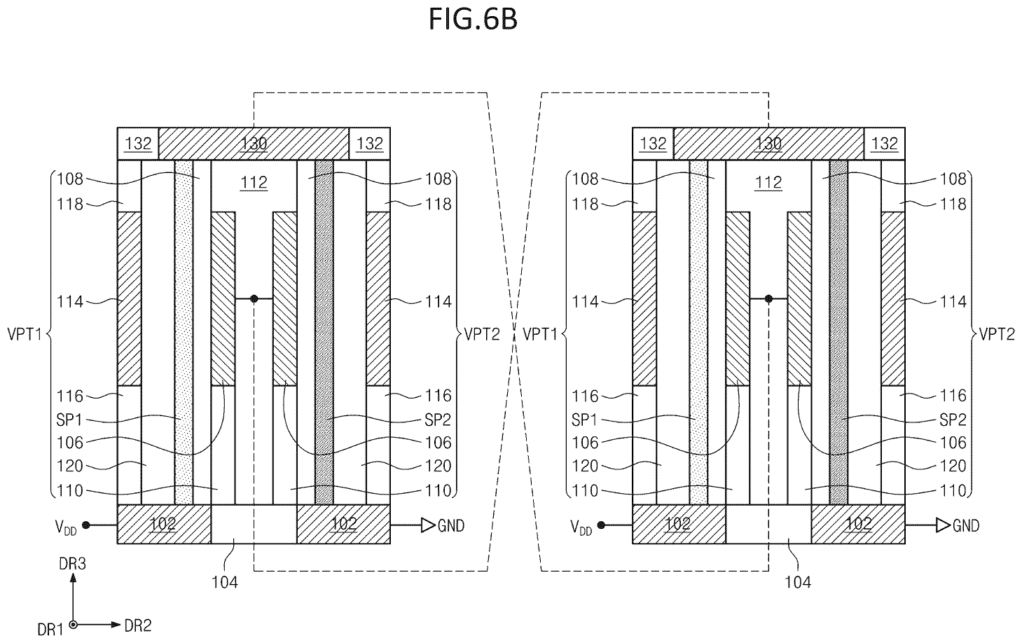

FIG. 5A is a plan view of a cell array structure according to example embodiments. FIG. 5B is a cross-sectional view taken along lines A-A′ and B-B′ of FIG. 5A. FIG. 5C is a cross-sectional view taken along lines C-C′ and D-D′ of FIG. 5A. FIG. 6A shows an inverter circuit including a first vertical peripheral transistor and a second vertical peripheral transistor of FIGS. 5A to 5C. FIG. 6B shows a latch circuit including a first vertical peripheral transistor and a second vertical peripheral transistor of FIGS. 5A to 5C.

Referring to FIGS. 5A to 5C, a substrate 100 may be provided. The substrate 100 may be disposed in the cell array region CAR and the upper peripheral region UPR. The substrate 100 may include a first surface 100a and a second surface 100b facing opposite directions. The first surface 100a and the second surface 100b may extend along the first direction DR1 and the second direction DR2. The first surface 100a and the second surface 100b may be spaced apart from each other along the third direction DR3. For example, the first direction DR1, the second direction DR2, and the third direction DR3 may be perpendicular to each other. The substrate 100 may include a semiconductor material. For example, the substrate 100 may include silicon (Si), germanium (Ge), or silicon-germanium (SiGe). The substrate 100 may have a first conductivity type. For example, the first conductivity type may be p-type or n-type. When the conductivity type of the substrate 100 is p-type, the substrate 100 may be a silicon (Si) substrate containing Group 3 elements or Group 2 elements as impurities. For example, Group 3 elements may include boron (B), aluminum (Al), gallium (Ga), or indium (In). When the conductivity type of the substrate 102 is n-type, it may be a silicon (Si) substrate containing Group 5 elements, Group 6 elements, or Group 7 elements as impurities. For example, group 5 elements may include phosphorus (P), arsenic (As), or antimony (Sb). When the first conductivity type is p-type or n-type, the second conductivity type may be n-type or p-type, respectively. The substrate 100 may be an epi layer formed through an epitaxial growth process.

First conductive lines 102 may be provided on the substrate 100. The first conductive lines 102 may extend along the first direction DR1. The first conductive lines 102 may be arranged along the second direction DR2. For example, the first conductive lines 102 may be parallel to each other. The first conductive lines 102 in the cell array region CAR may be bit lines. The first conductive lines 102 in the upper peripheral region UPR may be signal transmission lines for peripheral circuits. The first conductive lines 102 may be electrically connected to lower portions of the vertical cell transistors VCT, the first vertical peripheral transistors VPT1, and the second vertical peripheral transistors VPT2. In example embodiments, the first conductive lines 102 electrically connected to the first vertical peripheral transistors VPT1 and the first conductive lines 102 electrically connected to the second vertical peripheral transistors VPT2 may be electrically separated (e.g., insulated) from each other. For example, the first conductive lines 102 electrically connected to the first vertical peripheral transistors VPT1 and the first conductive lines 102 electrically connected to the second vertical peripheral transistors VPT2 may be spaced apart from each other along the first direction DR1. In example embodiments, the first conductive lines 102 electrically connected to the first vertical peripheral transistors VPT1 may be electrically separated from each other. For example, the first conductive lines 102 electrically connected to the first vertical peripheral transistors VPT1 immediately adjacent to each other may be spaced apart from each other along the first direction DR1. In example embodiments, the first conductive lines 102 electrically connected to the second vertical peripheral transistors VPT2 may be electrically separated from each other. For example, the first conductive lines 102 electrically connected to the second vertical peripheral transistors VPT2 immediately adjacent to each other may be spaced apart from each other along the first direction DR1. The first conductive lines 102 may include an electrically conductive material. For example, the first conductive lines 102 may include a doped polysilicon, metal (e.g., Al, Cu, Ti, Ta, Ru, W, Mo, Pt, Ni, Co), a conductive Metal nitride (e.g. TiN, TaN, WN, NbN, TiAlN, TiSiN, TaSiN, RuTiN), a conductive metal silicide, and/or a conductive metal oxide (e.g. PtO, RuO₂, IrO₂, SRO(SrRuO₃), BSRO((Ba,Sr) RuO₃), CRO(CaRuO₃), LSCo). The first conductive lines 102 may have a single-layer or multi-layer structure. In one embodiment, the first conductive lines 102 may include a two-dimensional semiconductor material. For example, the first conductive lines 102 may include graphene, carbon nanotubes, or a combination thereof.

Lower insulating layers 104 may be provided on the substrate 100. Lower insulating layers 104 may be provided between the first conductive lines 102, respectively. The lower insulating layers 104 and first conductive lines 102 may be alternately arranged along the second direction DR2. For example, the lower insulating layers 104 may at least partially fill the region between the first conductive lines 102. Although the lower insulating layers 104 are shown as being provided only on the sides of the first conductive lines 102, this is illustrative. In an example, the lower insulating layers 104 may extend between the substrate 100 and the first conductive lines 102 and be connected to each other. The lower insulating layers 104 extend along the first direction DR1 and may be arranged along the second direction DR2. The lower insulating layers 104 may include an insulating material. For example, the lower insulating layers 104 may include silicon oxide, silicon nitride, or silicon oxynitride.

First semiconductor patterns SP1 may be provided in the cell array region CAR and the upper peripheral region UPR. First semiconductor patterns SP1 may be provided on the first conductive lines 102. The first semiconductor patterns SP1 may be arranged along the first direction DR1 and the second direction DR2. The first semiconductor patterns SP1 may be electrically connected to the first conductive lines 102. For example, the first semiconductor patterns SP1 arranged along the first direction DR1 may be electrically connected to one first conductive line 102. The first semiconductor patterns SP1 disposed in the cell array region CAR and the first semiconductor patterns SP1 disposed in the upper peripheral region UPR may be electrically connected to different first conductive lines 102. The first semiconductor pattern SP1 may extend along the third direction DR3. The first semiconductor patterns SP1 may have a first conductivity type. The first semiconductor patterns SP1 of the cell array region CAR may be included in each of the vertical cell transistors VCT. The first semiconductor patterns SP1 of the upper peripheral region UPR may be included in each of the first vertical peripheral transistors VPT1.

Second semiconductor patterns SP2 may be provided in the upper peripheral region UPR. Second semiconductor patterns SP2 may be provided on the first conductive lines 102. The second semiconductor patterns SP2 may be arranged along the first direction DR1 and the second direction DR2. The second semiconductor patterns SP2 may be electrically connected to the first conductive lines 102. For example, the second semiconductor patterns SP2, arranged along the first direction DR1, may be electrically connected to one first conductive line 102. The second semiconductor patterns SP2 and the first semiconductor patterns SP1 may be electrically connected to different first conductive lines 102. The second semiconductor patterns SP2 may extend along the third direction DR3. The second semiconductor patterns SP2 may have a second conductivity type. For example, the conductivity type of the first semiconductor patterns SP1 may be p-type, and the conductivity type of the second semiconductor patterns SP2 may be n-type. The second semiconductor patterns SP2 may each be included in the second vertical peripheral transistors VPT2.

Second conductive lines 106 may be provided on the first conductive lines 102. The second conductive lines 106 may be spaced apart from the first conductive lines 102 along the third direction DR3. The second conductive lines 106 may extend along the second direction DR2. The second conductive lines 106 may be arranged along the first direction DR1. For example, the second conductive lines 106 may be parallel to each other. The second conductive lines 106 may face the first semiconductor patterns SP1 and the second semiconductor patterns SP2 along the first direction DR1. The second conductive lines 106 may at least partially overlap the first semiconductor patterns SP1 and the second semiconductor patterns SP2 along the first direction DR1.

The second conductive lines 106 may be alternately disposed on one side and the other side of the first semiconductor patterns SP1 along the first direction DR1. One side and the other side of the first semiconductor patterns SP1 may be both side surfaces of the first semiconductor patterns SP1 that are sequentially arranged along the first direction DR1. For example, one second conductive line 106 may be disposed on one side of one first semiconductor pattern SP1. For example, the other second conductive line 106 may be provided on the other side of the other first semiconductor pattern SP1 immediately adjacent to the one first semiconductor pattern SP1 along the first direction DR1.

The second conductive lines 106 may be alternately disposed on one side and the other side of the second semiconductor patterns SP2 arranged along the first direction DR1. One side and the other side of the second semiconductor patterns SP2 may be both sides of the second semiconductor patterns SP2 sequentially arranged along the first direction DR1. For example, one second conductive line 106 may be disposed on one side of one second semiconductor pattern SP2. For example, the other second conductive line 106 may be provided on the other side of the other second semiconductor pattern SP2 immediately adjacent to the one second semiconductor pattern SP2 along the first direction DR1.

The second conductive lines 106 in the cell array region CAR may be word lines. In example embodiments, the second conductive lines 106 may be gate electrodes of the vertical cell transistors VCT that turn the vertical cell transistors VCT on and/or off. The second conductive lines 106 in the upper peripheral region UPR may be gate electrodes of the first vertical peripheral transistors VPT1 and the second vertical peripheral transistors VPT2. The second conductive lines 106 may be configured to turn on and/or off the first vertical peripheral transistors VPT1 and the second vertical peripheral transistors VPT2.

The second conductive lines 106 may include an electrically conductive material. For example, the second conductive lines 106 may include doped polysilicon, metal (e.g., Al, Cu, Ti, Ta, Ru, W, Mo, Pt, Ni, Co), conductive metal nitrides (e.g. TiN, TaN, WN, NbN, TiAlN, TiSiN, TaSiN, RuTiN), conductive metal silicides, and/or conductive metal oxides (e.g. PtO, RuO₂, IrO₂, SRO(SrRuO₃), BSRO((Ba,Sr) RuO₃), CRO(CaRuO₃), LSCo). The second conductive lines 106 may have a single-layer or multi-layer structure. In one embodiment, the second conductive lines 106 may include a two-dimensional semiconductor material. For example, the second conductive lines 106 may include graphene, carbon nanotubes, or a combination thereof.

First gate insulating layers 108 may be provided between the second conductive lines 106 and the first semiconductor patterns SP1 and between the second conductive lines 106 and the second semiconductor patterns SP2. The first gate insulating layer 108 may electrically separate the first semiconductor patterns SP1 and the second conductive line 106 that are immediately adjacent to each other. The first gate insulating layer 108 may electrically separate the second semiconductor patterns SP2 and the second conductive line 106 that are immediately adjacent to each other. The first gate insulating layers 108 may extend along side surfaces of the first semiconductor patterns SP1 facing the second conductive lines 106. The first gate insulating layers 108 may extend along side surfaces of the second semiconductor patterns SP2 facing the second conductive lines 106. The first gate insulating layers 108 may extend along the third direction DR3. The lower portions of the first gate insulating layers 108 may be in contact with the first conductive lines 102 and lower insulating layers 104. The top of the first gate insulating layer 108 may be in contact with the upper insulating layers 132. The first gate insulating layers 108 may be gate insulating layers for the second conductive lines 106 in the vertical cell transistors VCT, the first vertical peripheral transistors VPT1, and the second vertical peripheral transistors VPT2. The first gate insulating layer 108 may include a low-k dielectric (e.g., a material having a dielectric constant that is less than that of silicon oxide), silicon oxide, and high-k dielectric (e.g., a material having a dielectric constant that is greater than that of silicon oxide). The high dielectric material may be a metal oxide or metal oxynitride. For example, the first gate insulating layer 108 may include HfO₂, HfSiO, HfSiON, HfTaO, HfTiO, HfZrO, ZrO₂, Al₂O₃, or a combination thereof.

First insulating patterns 110 may be provided on bottom surfaces of the second conductive lines 106. The first insulating patterns 110 may extend along bottom surfaces of the second conductive lines 106. The first insulating patterns 110 may extend in the second direction DR2. The first insulating patterns 110 may be arranged along the first direction DR1. First insulating patterns 110 may be provided on side surfaces of the first gate insulating layers 108. The first insulating patterns 110 may contact the immediately adjacent first gate insulating layers 108. First insulating patterns 110 may be provided on the first conductive lines 102 and lower insulating layers 104. The first insulating patterns 110 may be configured to electrically separate the first conductive lines 102 and the second conductive lines 106. The first insulating patterns 110 may include an insulating material. For example, the first insulating patterns 110 may include silicon oxide, silicon nitride, or silicon oxynitride.

Second insulating patterns 112 may be provided between the first gate insulating layers 108. The second insulating patterns 112 may at least partially cover the second conductive lines 106 and the first insulating patterns 110. The second insulating pattern 112 may at least partially fill the region between a pair of first gate insulating layers 108 that are immediately adjacent to each other. The second insulating patterns 112 may extend along the second direction DR2. The second insulating patterns 112 may be arranged along the first direction DR1. The second insulating patterns 112 may extend along the third direction DR3. The second insulating pattern 112 may be configured to electrically separate a pair of second conductive lines 106 that are immediately adjacent to each other. A pair of second conductive lines 106 immediately adjacent to each other may be spaced apart from each other by the second insulating pattern 112. The second insulating patterns 112 may include an insulating material. For example, the second insulating patterns 112 may include silicon oxide, silicon nitride, and/or silicon oxynitride.

Third conductive lines 114 may be provided on the first conductive lines 102. The third conductive line 114 may be provided on the opposite side of the second conductive line 106 with the first semiconductor pattern SP1 or the second semiconductor pattern SP2 interposed therebetween. The third conductive line 114 may be disposed between a pair of first semiconductor patterns SP1 that are immediately adjacent to each other and between a pair of second semiconductor patterns SP2 that are immediately adjacent to each other. The third conductive lines 114 may extend along the second direction DR2. The third conductive lines 114 may be arranged along the first direction DR1. For example, the third conductive lines 114 may be parallel to each other. The third conductive lines 114 may at least partially overlap the first semiconductor patterns SP1 and the second semiconductor patterns SP2 along the first direction DR1. The third conductive lines 114 may include an electrically conductive material. For example, the third conductive lines 114 may include doped polysilicon, metal (e.g., Al, Cu, Ti, Ta, Ru, W, Mo, Pt, Ni, Co), conductive metal nitrides (e.g. TiN, TaN, WN, NbN, TiAlN, TiSiN, TaSiN, RuTiN), conductive metal silicides, and/or conductive metal oxides (e.g. PtO, RuO₂, IrO₂, SRO(SrRuO₃), BSRO((Ba,Sr) RuO₃), CRO(CaRuO₃), LSCo). The third conductive lines 114 may have a single-layer or multi-layer structure. In one embodiment, the third conductive lines 114 may include a two-dimensional semiconductor material. For example, the third conductive lines 114 may include graphene, carbon nanotubes, or a combination thereof. The third conductive lines 114 may be back gate electrodes of the vertical cell transistors VCT, the first vertical peripheral transistors VPT1, and the second vertical peripheral transistors VPT2. The third conductive lines 114 may increase the threshold voltage of the vertical cell transistors VCT, the first vertical peripheral transistors VPT1, and the second vertical peripheral transistors VPT2. Accordingly, even if the vertical cell transistors VCT, the first vertical peripheral transistors VPT1, and the second vertical peripheral transistors VPT2 have small sizes, a decrease in threshold voltage and deterioration of leakage current characteristics may be prevented.

Third insulating patterns 116 may be provided on bottom surfaces of the third conductive lines 114. The third insulating patterns 116 may extend along bottom surfaces of the third conductive lines 114. The third insulating patterns 116 may extend in the second direction DR2. The third insulating patterns 116 may be arranged along the first direction DR1. Third insulating patterns 116 may be provided on the first conductive lines 102 and lower insulating layers 104. The third insulating patterns 116 may be configured to electrically separate the first conductive lines 102 and the third conductive lines 114. The third insulating patterns 116 may include an insulating material. For example, the third insulating patterns 116 may include silicon oxide, silicon nitride, and/or silicon oxynitride.

Fourth insulating patterns 118 may be provided on the third conductive lines 114. The fourth insulating patterns 118 may be provided on opposite sides of the third insulating patterns 116 with the third conductive lines 114 interposed therebetween. The fourth insulating patterns 118 may extend along the upper surfaces of the third conductive lines 114. The fourth insulating patterns 118 may extend in the second direction DR2. The fourth insulating patterns 118 may be arranged along the first direction DR1. The fourth insulating patterns 118 may include an insulating material. For example, the fourth insulating patterns 118 may include silicon oxide, silicon nitride, and/or silicon oxynitride.

Second gate insulating layers 120 may be provided between the third conductive lines 114 and the first semiconductor patterns SP1 and between the third conductive lines 114 and the second semiconductor patterns SP2. There is. The second gate insulating layers 120 may extend along the second direction DR2. The second gate insulating layer 120 may electrically separate the first semiconductor pattern SP1 and the third conductive line 114 that are immediately adjacent to each other. The second gate insulating layer 120 may electrically separate the second semiconductor pattern SP2 and the third conductive line 114 that are immediately adjacent to each other. Second gate insulating layers 120 may be provided on side surfaces of the first semiconductor patterns SP1 and side surfaces of the second semiconductor patterns SP2. The second gate insulating layers 120 may extend along the third direction DR3. The lower portion of the second gate insulating layer 120 may be in contact with the first conductive line 102 and the lower insulating layers 104. The top of the second gate insulating layer 120 may be in contact with the upper insulating layers 132. The second gate insulating layers 120 may be gate insulating layers for the third conductive lines 114 in the vertical cell transistors (VCT), the first vertical peripheral transistors VPT1, and the second vertical peripheral transistors VPT2. The second gate insulating layer 120 may include a low-k dielectric, silicon oxide, and/or high-k dielectric. The high dielectric material may be a metal oxide or metal oxynitride. For example, the second gate insulating layer 120 may include HfO₂, HfSiO, HfSiON, HfTaO, HfTiO, HfZrO, ZrO₂, Al₂O₃, and/or a combination thereof.

In the cell array region CAR, first semiconductor patterns SP1, second conductive lines 106, first gate insulating layers 108, third conductive lines 114, and second gate insulating layers 120 may define vertical cell transistors VCT. Vertical cell transistors VCT may have a first polarity. For example, vertical cell transistors VCT may be NMOS transistors.

In the upper peripheral region UPR, first semiconductor patterns SP1, second conductive lines 106, first gate insulating layers 108, third conductive lines 114, and second gate insulating layers 120 may define first vertical peripheral transistors VPT1. The first vertical peripheral transistors VPT1 may have a first polarity. For example, the first vertical peripheral transistors VPT1 may be NMOS transistors.

In the upper peripheral region UPR, second semiconductor patterns SP2, second conductive lines 106, first gate insulating layers 108, third conductive lines 114, and second gate insulating layers 120 may define second vertical peripheral transistors VPT2. The first vertical peripheral transistors VPT1 may have a first polarity. For example, the second vertical peripheral transistors VPT2 may be PMOS transistors.

At least some of the first peripheral circuits of the semiconductor memory device 10 may be implemented by first vertical peripheral transistors VPT1 and second vertical peripheral transistors VPT2. Accordingly, at least some of the first peripheral circuits of the semiconductor memory device 10 may be disposed in the cell array structure CS. For example, the first vertical peripheral transistors VPT1 and the second vertical peripheral transistors VPT2 may form an inverter circuit and/or a latch circuit. Latch circuits may be used in the implementation of, for example, a fuse box circuit or an MRS circuit.

First pads 130 may be provided on the first and second semiconductor patterns SP1 and SP2 of the cell array region CAR, respectively. For example, the first pads 130 may at least partially vertically overlap the first semiconductor patterns SP1 and the second semiconductor patterns SP2, respectively. The first pads 130 may be electrically connected to the first semiconductor patterns SP1 and the second semiconductor patterns SP2, respectively. For example, the first pads 130 may directly contact the first semiconductor patterns SP1 and the second semiconductor patterns SP2. The first pads 130 may be electrically separated from each other.

Second pads 131 may be provided on the first semiconductor patterns SP1 and the second semiconductor patterns SP2 in the upper peripheral region UPR. The second pads 131 may be connected to each other as needed. For example, the first semiconductor pattern 108 and the second semiconductor pattern 112 that are immediately adjacent to each other may be electrically connected to each other through one second pad 131. The second pads 131 may extend in the first direction DR1 or the second direction DR2. One second pad 131 that electrically connects the first semiconductor pattern 108 and the second semiconductor pattern 112 immediately adjacent to each other may be configured to at least partially overlap a first semiconductor pattern 108 and a second semiconductor pattern 112 immediately adjacent to each other along the third direction DR3. The electrical connection relationship between the second pads 131 and the first and second semiconductor patterns SP1 and SP2 may be selected so as to implement a desired circuit. As shown in FIG. 6A, the first vertical peripheral transistor VPT1 having a first polarity and the second vertical peripheral transistor VPT2 having a second polarity (e.g., PMOS transistor) are electrically connected to the inverter. A circuit may be constructed. For example, the first vertical peripheral transistor VPT1 having the first polarity may be an NMOS transistor. For example, the second vertical peripheral transistor VPT2 having the second polarity may be a PMOS transistor. As shown in FIG. 6B, a pair of first vertical peripheral transistors VPT1 having a first polarity and a pair of second vertical peripheral transistors VPT2 having a second polarity (e.g., PMOS transistor) may be electrically connected to form a latch circuit. For example, a pair of first vertical peripheral transistors VPT1 having a first polarity may be a pair of NMOS transistors. For example, a pair of second vertical peripheral transistors VPT2 having a second polarity may be a pair of PMOS transistors. The second pads 131 may include an electrically conductive material. For example, the second pads 131 may include doped polysilicon, conductive metal nitride, conductive metal silicon nitride, metal carbonitride, conductive metal silicide, conductive metal oxide, two-dimensional material, metal, and/or a metal alloy.

An upper insulating layer 132 may be provided between the first pads 130 and the second pads 131. The upper insulating layer 132 may at least partially fill the region between the first pads 130 and the region between the second pads 131. The upper insulating layer 132 may electrically separate the first pads 130 and the second pads 131 from each other. In embodiments, the top surfaces of the upper insulating layers 132 are shown to be located at substantially the same height as the top surfaces of the first pads 130 and the second pads 131. In an example, the top surface of the upper insulating layer 132 may be located at a different height from the top surfaces of the first pads 130 and the second pads 131. The upper insulating layer 132 may include an insulating material. For example, the upper insulating layer 132 may include silicon oxide, silicon nitride, or silicon oxynitride.

Lower electrodes 142 may be provided in the cell array region CAR. Lower electrodes 142 may be provided on the first pads 130, respectively. The lower electrodes 142 may be arranged along the first direction DR1 and the second direction DR2. The lower electrodes 142 may completely or partially overlap the first pads 130 in the third direction DR3. The storage electrode 142 may contact the first pad 130. The lower electrodes 142 may contact all or part of the upper surfaces of the first pads 130. From a two-dimensional perspective, the lower electrodes 142 may have various shapes, such as circular, oval, rectangular, square, diamond, or hexagonal shapes. The lower electrode 142 may include a conductive semiconductor material, conductive metal nitride, conductive metal silicon nitride, metal carbonitride, conductive metal silicide, conductive metal oxide, and/or metal.

A capacitor dielectric layer 144 may be provided on the lower electrodes 142. The capacitor dielectric layer 144 may extend along the surfaces of the lower electrodes 142. The capacitor dielectric layer 144 may further extend onto the upper surface of the upper insulating layer 132 between the lower electrodes 142 and the upper surface of the first pads 130. The capacitor dielectric layer 144 may include a ferroelectric material, an antiferroelectric material, and/or a paraelectric material. For example, the capacitor dielectric layer 144 may be a ferroelectric material, an antiferroelectric material, a paraelectric material, a combination of a ferroelectric material and an antiferroelectric material, a combination of a ferroelectric material and a paraelectric material, a combination of a paraelectric material and an antiferroelectric material, and/or a combination of a ferroelectric material, antiferroelectric material, and paraelectric material.

An upper electrode 146 may be provided on the capacitor dielectric layer 144. The upper electrode 146 may be electrically separated from the lower electrodes 142 with the capacitor dielectric layer 144 interposed therebetween. The upper electrode 146 may include a conductive semiconductor material, conductive metal nitride, conductive metal silicon nitride, metal carbonitride, conductive metal silicide, conductive metal oxide, and/or metal.

The lower electrodes 142, the capacitor dielectric layer 144, and the upper electrode 146 may form a capacitor. Charge may be stored in the capacitor by the voltage difference applied to the lower electrode 142 and the upper electrode 146. The voltage applied to the lower electrode 142 may be controlled by a vertical cell transistor VCT. The voltage applied to the upper electrode 146 may be provided from a peripheral circuit disposed in the peripheral circuit structure. For example, the upper electrode 146 may be connected to a peripheral circuit disposed in the peripheral circuit structure by vertical conductive lines VCL and horizontal conductive lines HCL.

The upper peripheral region UPR might not include a capacitor. A capping layer 150 may be disposed in the upper peripheral region UPR. The capping layer 150 may be provided on the upper insulating layer 132 and the second pads 131. Vertical conductive lines VCL and horizontal conductive lines HCL that provide electrical connections between the second pads 131 and other components may be provided in the capping layer 150. The capping layer 150 may include an insulating material. For example, the capping layer 150 may include silicon oxide, silicon nitride, or silicon oxynitride.

In embodiments, the semiconductor memory device 10 may include a variable resistance pattern that may be switched between two resistance states by an electrical pulse instead of a capacitor. Variable resistance patterns may contain phase-change materials whose crystal state changes depending on the amount of current, perovskite compounds, transition metal oxides, magnetic materials, ferromagnetic materials, or antiferromagnetic materials.

When the cell transistor is a planar transistor, the upper peripheral region UPR of the cell array structure CS may be a region where peripheral circuits are placed. As a vertical channel transistor is used as a cell transistor, the peripheral circuit may be disposed in the peripheral circuit structure PS in FIG. 2 located at the bottom of the cell array structure CS, but might not be disposed in the upper peripheral region UPR of the cell array structure CS.

The peripheral circuit of the present invention may be formed by dividing into a peripheral circuit structure PS in FIG. 2 and a cell array structure CS. Accordingly, the size of the semiconductor memory device 10 may be reduced or the degree of integration of the semiconductor memory device 10 may be increased compared to the case where the peripheral circuit is placed only on the peripheral circuit structure PS in FIG. 2. As a result, a semiconductor memory device 10 with a reduced size or increased integration may be provided.

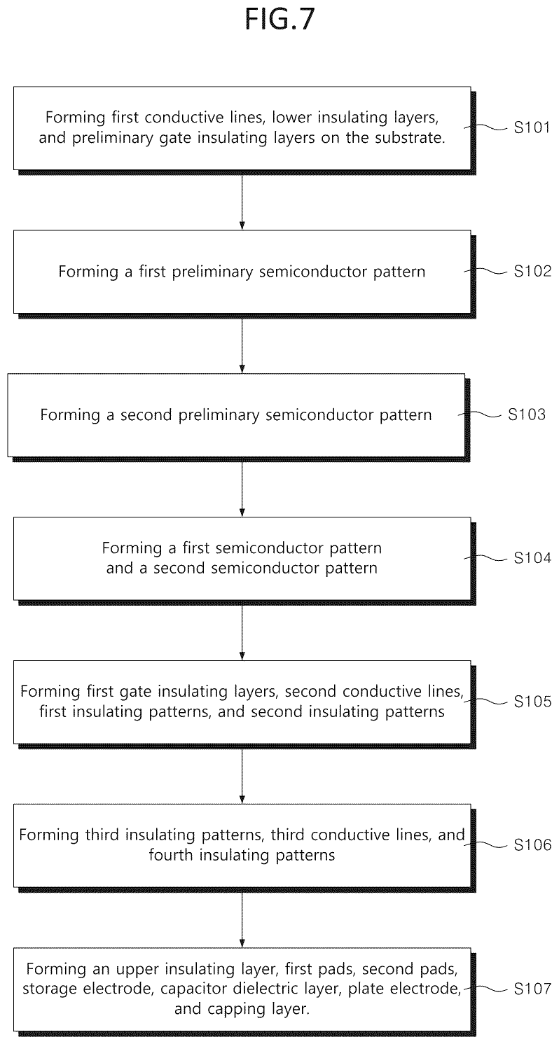

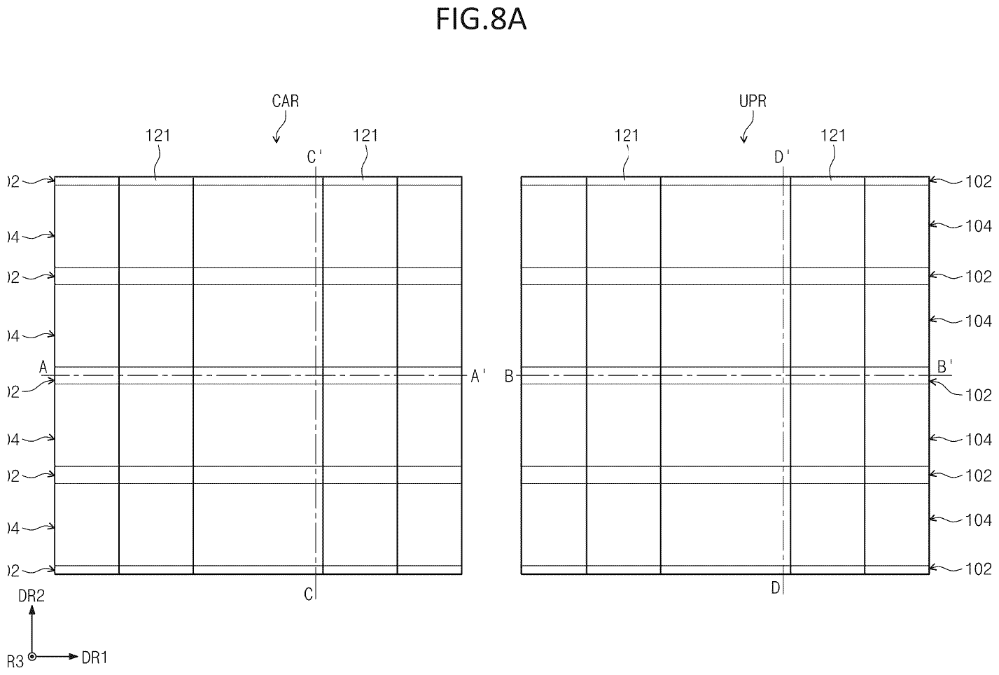

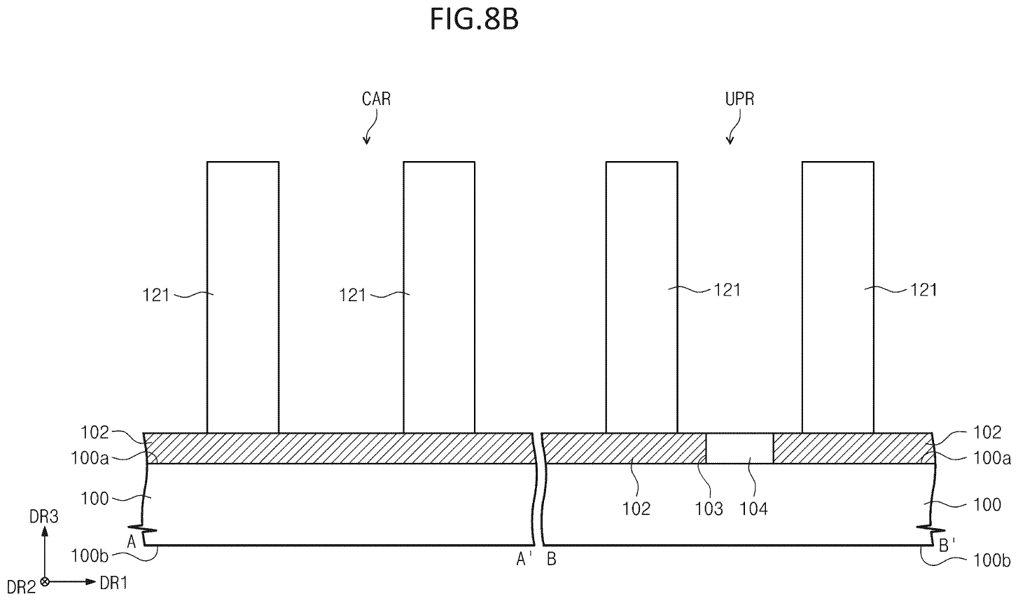

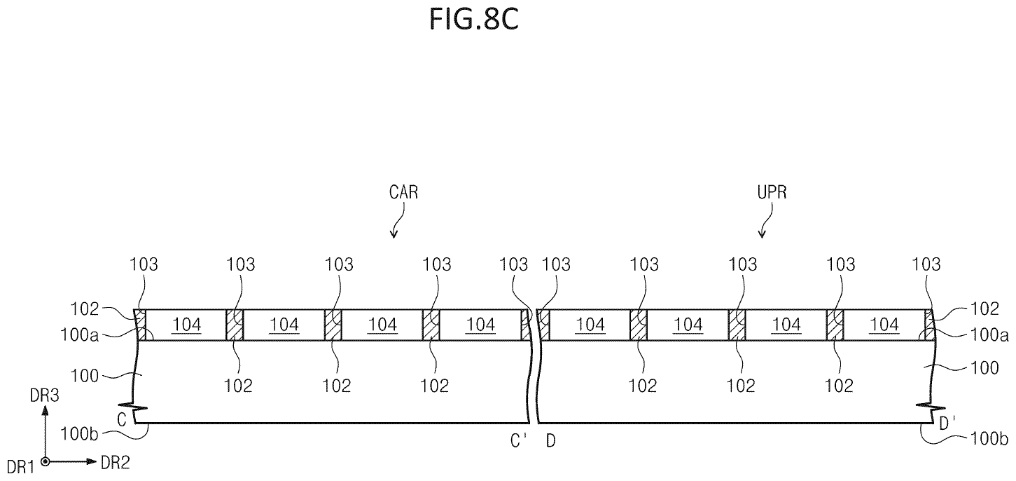

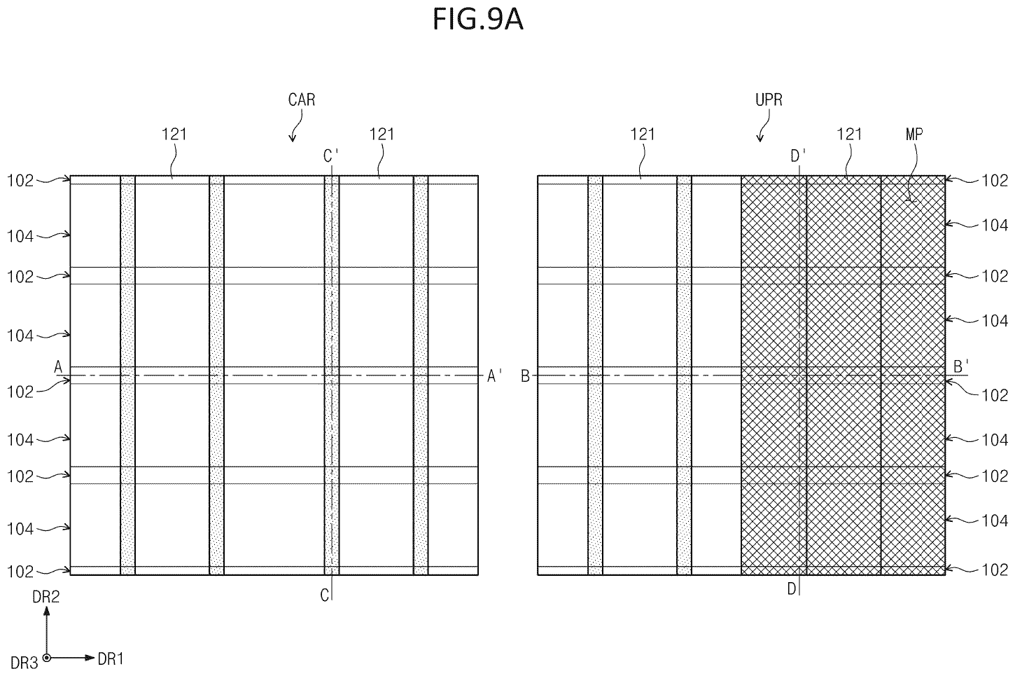

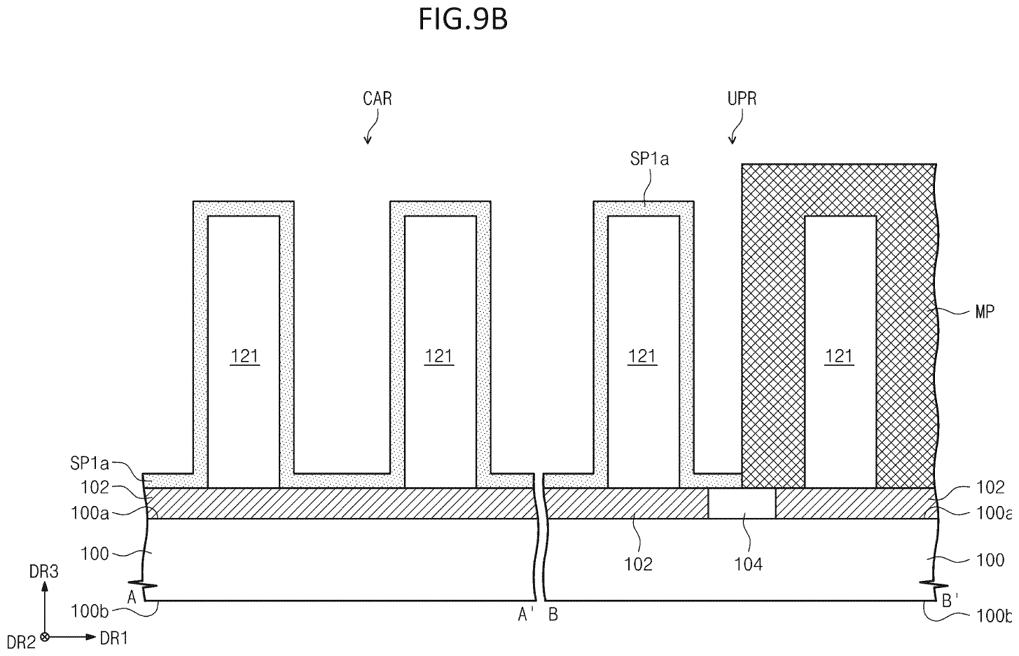

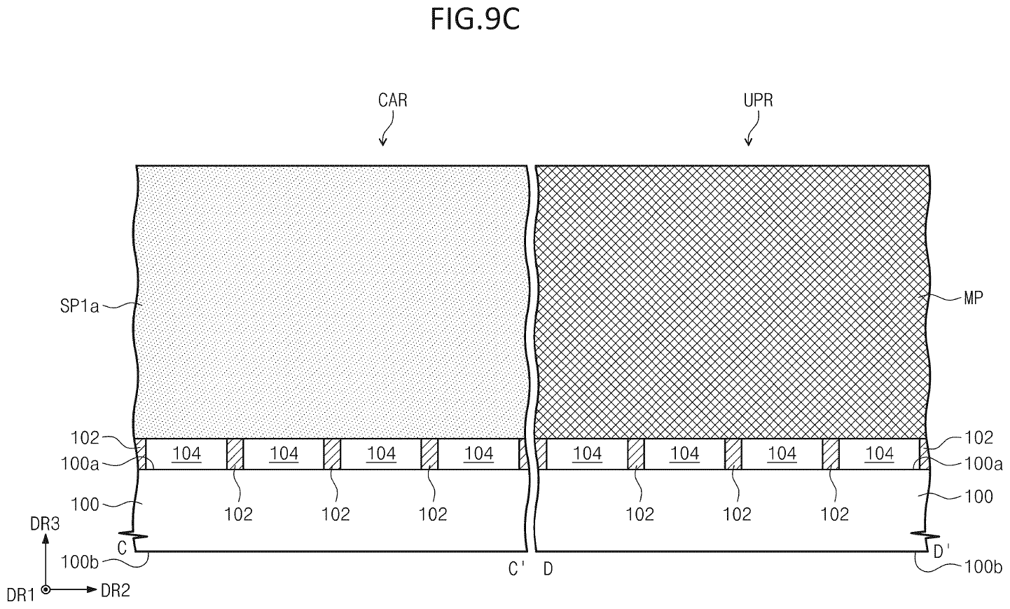

FIG. 7 is a flowchart illustrating a method of manufacturing a cell array structure according to an embodiment. FIGS. 8A, 9A, 10A, 11A, 12A, and 13A are plan views illustrating the manufacturing method of FIG. 7. FIGS. 8B, 8C, 9B, 9C, 10B, 10C, 11B, 11C, 12B, 12C, 13B, and 13C are cross-sectional views corresponding to lines A-A′, B-B′, C-C′, and D-D′ in FIGS. 9A, 10A, 11A, 12A, and 13A illustrating the manufacturing method of FIG. 7.

Referring to FIGS. 7, 8A, 8B, and 8C, first conductive lines 102 and lower insulating layers 104, and preliminary gate insulating layers 121 may be disposed on the substrate 100 provided in the cell array region CAR and the upper peripheral region UPR. (S101) the substrate 100 may include a semiconductor material. For example, the substrate 100 may include silicon (Si), germanium (Ge), or silicon-germanium (SiGe). The substrate 100 may include a first surface 100a and a second surface 100b facing opposite directions. The first surface 100a and the second surface 100b may extend along the first direction DR1 and the second direction DR2. The first surface 100a and the second surface 100b may be spaced apart from each other along the third direction DR3. The substrate 100 may have a first conductivity type. For example, the first conductivity type may be p-type or n-type. When the conductivity type of the substrate 100 is p-type, the substrate 100 may be a silicon (Si) substrate containing Group 3 elements (e.g., boron (B), aluminum (Al), gallium (Ga), indium (In), etc.) or Group 2 elements as impurities. When the conductivity type of the substrate 102 is n-type, the substrate 102 may be a silicon (Si) substrate containing group 5 elements (e.g., phosphorus (P), arsenic (As), antimony (Sb), etc.), group 6, or group 7 elements as impurities. Hereinafter, the region where the conductivity type is n-type may include impurities of group 5, 6, or 7 elements. When the first conductivity type is p-type or n-type, the second conductivity type may be n-type or p-type, respectively. The substrate 100 may be an epi layer formed through an epitaxial growth process.

Lower insulating layers 104 may be disposed on the substrate 100. Trenches 103 may be disposed between the lower insulating layers 104. The trenches 103 may provide a region where the first conductive lines 102 are disposed. Although the trenches 103 are shown exposing the first side 100a, this is illustrative. In an example, the trenches 103 may be disposed on top of the lower insulating layers 104 to expose the lower portions of the lower insulating layers 104. The trenches 103 may extend along the first direction DR1. The trenches 103 may be spaced apart from each other in the second direction DR2. The lower insulating layers 104 may include an insulating material. For example, the lower insulating layers 104 may include silicon oxide, silicon nitride, and/or silicon oxynitride. In one embodiment, the lower insulating layers 104 may be formed by patterning an insulating layer deposited on the substrate 100. For example, the insulating layer may be formed on the substrate 100 by chemical vapor deposition (CVD), physical vapor deposition (PVD), and/or atomic layer deposition (ALD).

First conductive lines 102 may be disposed within each of the trenches 103. The first conductive lines 102 may extend along the first direction DR1. The first conductive lines 102 may be spaced apart from each other in the second direction DR2. The first conductive lines 102 may include an electrically conductive material. For example, the first conductive lines 102 may include doped polysilicon, metal (e.g., Al, Cu, Ti, Ta, Ru, W, Mo, Pt, Ni, Co), conductive metal nitrides (e.g. TiN, TaN), WN, NbN, TiAlN, TiSiN, TaSiN, RuTiN), conductive metal silicides, and/or conductive metal oxides (e.g. PtO, RuO₂, IrO₂, SRO(SrRuO₃), BSRO((Ba,Sr) RuO₃), CRO(CaRuO₃), LSCo). The first conductive lines 102 may have a single-layer or multi-layer structure. In one embodiment, the first conductive lines 102 may include a two-dimensional semiconductor material. For example, the first conductive lines 102 may include graphene, carbon nanotubes, or a combination thereof. The first conductive lines 102 may be formed by at least partially filling the trench 103 with an electrically conductive material. For example, at least partially filling trench 103 with an electrically conductive material may include depositing an electrically conductive layer in the region on the top surface of lower insulating layer 104 and across trench 103, and then removing the electrically conductive layer on lower insulating layer 104. For example, the electrically conductive layer may be disposed on the substrate 100 by a chemical vapor deposition (CVD) process, a physical vapor deposition (PVD) process, or an atomic layer deposition (ALD) process.

The preliminary gate insulating layers 121 may be disposed on the lower insulating layers 104 and the first conductive lines 102. The preliminary gate insulating layers 121 may extend along the second direction DR2. The preliminary gate insulating layers 121 may be arranged along the first direction DR1. For example, the preliminary gate insulating layers 121 may be spaced apart from each other along the first direction DR1. The preliminary gate insulating layers 121 may include a low-k dielectric, silicon oxide, and/or a high-k dielectric. The high dielectric material may be a metal oxide or metal oxynitride. For example, the preliminary gate insulating layers 121 may include HfO₂, HfSiO, HfSiON, HfTaO, HfTIO, HfZrO, ZrO₂, Al₂O₃, or a combination thereof. In example embodiments, an etch stop layer having an etch selectivity with respect to the preliminary gate insulating layer 121 may be disposed on the bottom surface of the preliminary gate insulating layer 121. The preliminary gate insulating layers 121 may be formed by patterning the deposited insulating layer. For example, the insulating layer may be disposed on the lower insulating layers 104 and the first conductive lines 102 by chemical vapor deposition (CVD), physical vapor deposition (PVD), or atomic layer deposition (ALD).

Referring to FIGS. 7, 9A, 9B, and 9C, a first preliminary semiconductor pattern SP1a may be formed (S101). The first preliminary semiconductor pattern SP1a may be formed on the first conductive lines 102, the lower insulating layers 104, and the preliminary gate insulating layers 121 (S102). The first preliminary semiconductor pattern SP1a may extend along surfaces of the first conductive lines 102, the lower insulating layers 104, and the preliminary gate insulating layers 121. For example, the first preliminary semiconductor pattern SP1a may be formed along the profiles of the first conductive lines 102, the lower insulating layers 104, and the preliminary gate insulating layers 121. The first preliminary semiconductor pattern SP1a may be formed by depositing a semiconductor material layer on the first conductive lines 102, the lower insulating layers 104, and the preliminary gate insulating layers 121. For example, depositing a semiconductor material layer may be performed by chemical vapor deposition (CVD), physical vapor deposition (PVD), or atomic layer deposition (ALD).

In one embodiment, before the first preliminary semiconductor pattern SP1a is disposed, the mask pattern MP may be disposed in a portion of the upper peripheral region UPR. The mask pattern MP may at least partially cover the preliminary gate insulating layers 121, the first conductive lines 102, and the lower insulating layers 104 provided in a portion of the upper peripheral region UPR. A portion of the upper peripheral region UPR may be a region where second vertical peripheral transistors are disposed.

The formation process of the first preliminary semiconductor pattern SP1a may be performed while the mask pattern MP is formed on the preliminary gate insulating layers 121, the first conductive lines 102, and the lower insulating layers 104. The mask pattern MP may be removed after forming the first preliminary semiconductor pattern SP1a.

The first preliminary semiconductor pattern SP1a may include an oxide semiconductor. For example, the first preliminary semiconductor pattern SP1a may include InₓGa_{y}Zn_{z}O, InₓGa_{y}Si_{z}O, InₓSn_{y}Zn_{z}O, InₓZn_{y}O, ZnₓO, ZnₓSn_{y}O, ZnₓO_{y}N, ZrₓZn_{y}Sn_{z}O, SnₓO, HfₓIn_{y}Zn_{z}O, GaₓZn_{y}Sn_{z}O, AlₓZn_{y}Sn_{z}O, YbₓGa_{y}Zn_{z}O, and/or InₓGa_{y}O. As example embodiments, the first preliminary semiconductor pattern SP1a may include Indium Gallium Zinc Oxide (IGZO). The first preliminary semiconductor pattern SP1a may include a single layer or multiple layers of an oxide semiconductor. The first preliminary semiconductor pattern SP1a may include an amorphous, crystalline, or polycrystalline oxide semiconductor. In example embodiments, the first preliminary semiconductor pattern SP1a may include a two-dimensional semiconductor material. For example, the 2D semiconductor material may include graphene, carbon nanotubes, or a combination thereof. The first preliminary semiconductor pattern SP1a may have a first conductivity type. For example, the conductivity type of the first preliminary semiconductor pattern SP1a may be p-type.

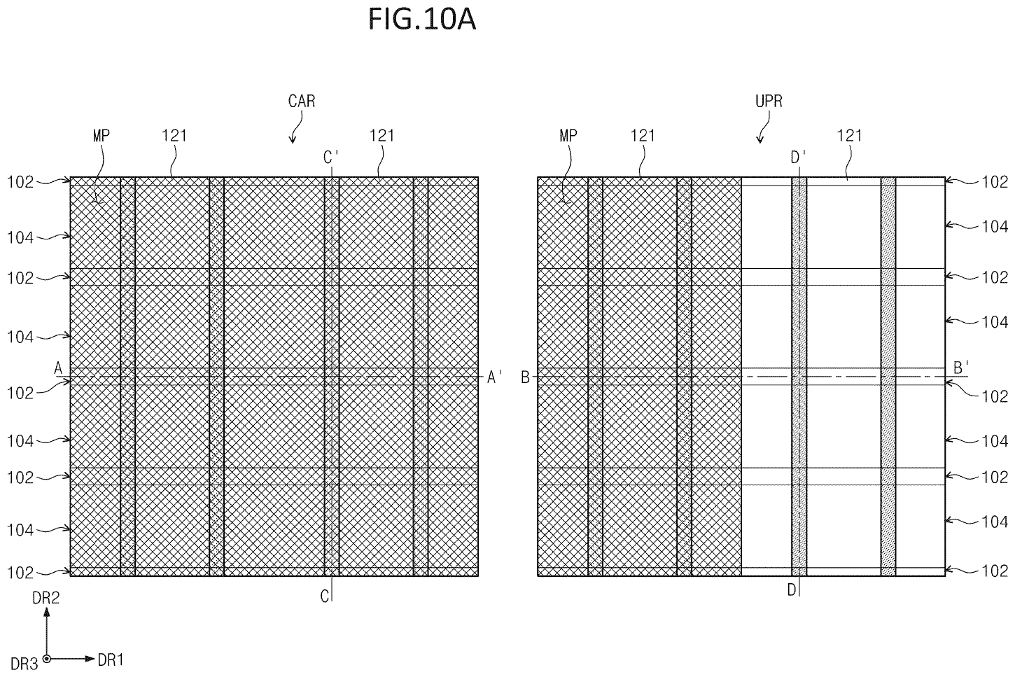

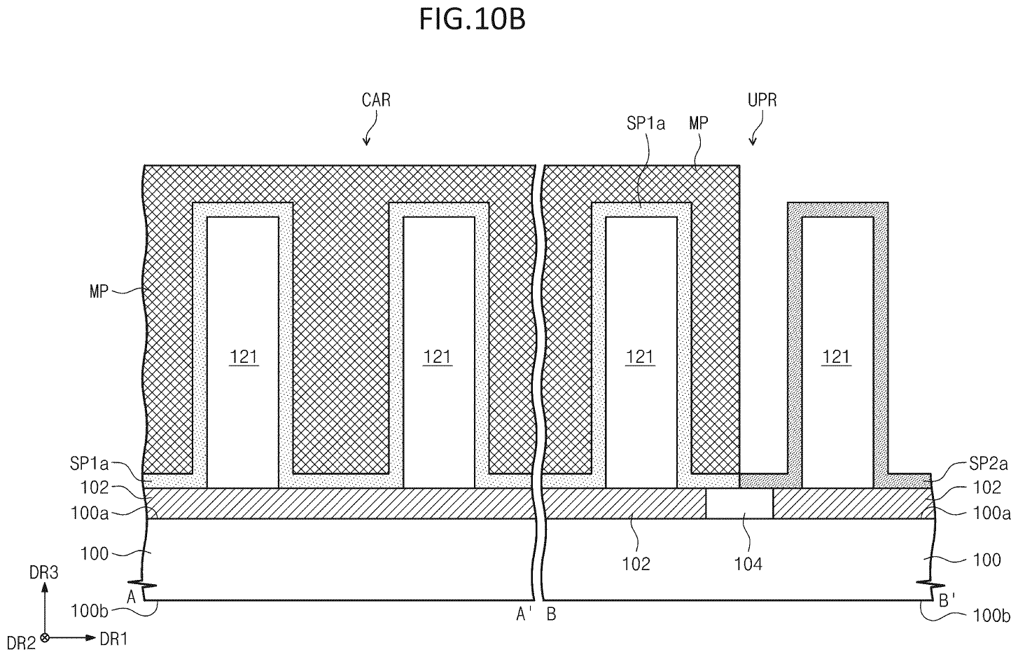

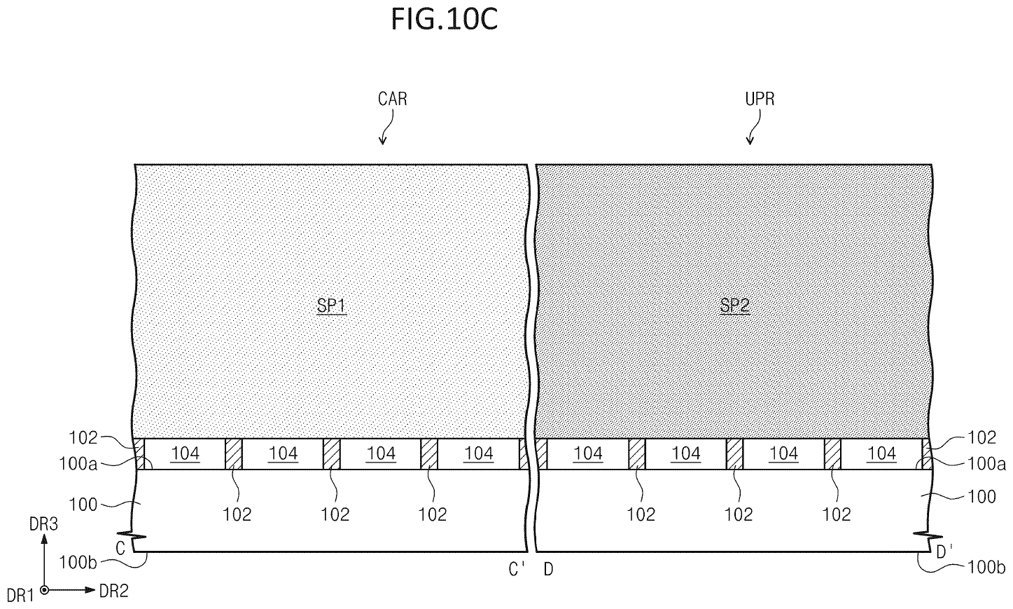

Referring to FIGS. 7, 10A, 10B, and 10C, a second preliminary semiconductor pattern SP2a may be disposed in the upper peripheral region UPR (S103). The second preliminary semiconductor pattern SP2a may be disposed in a portion of the upper peripheral region UPR. A portion of the upper peripheral region UPR may be a region in which the first preliminary semiconductor pattern SP1a is not disposed. The second preliminary semiconductor pattern SP2a may be disposed on the first conductive lines 102, the lower insulating layers 104, and the preliminary gate insulating layers 121 in a portion of the upper peripheral region UPR. The second preliminary semiconductor pattern SP2a may extend along surfaces of the first conductive lines 102, the lower insulating layers 104, and the preliminary gate insulating layers 121. For example, the second preliminary semiconductor pattern SP2a may be disposed along the profiles of the first conductive lines 102, the lower insulating layers 104, and the preliminary gate insulating layers 121. The second preliminary semiconductor pattern SP2a may be formed by depositing a semiconductor material layer on the first conductive lines 102, the lower insulating layers 104, and the preliminary gate insulating layers 121. For example, depositing a semiconductor material layer may be performed by chemical vapor deposition (CVD), physical vapor deposition (PVD), or atomic layer deposition (ALD).

In one embodiment, before the second preliminary semiconductor pattern SP1a is disposed, the mask pattern MP may be disposed in the cell array region CAR and other portions of the upper peripheral region UPR. Another portion of the upper peripheral region UPR may be a region where first vertical peripheral transistors are disposed. The mask pattern MP may at least partially cover the first preliminary semiconductor pattern SP1a in the cell array region CAR and a portion of the upper peripheral region UPR. A process of forming the second preliminary semiconductor pattern SP2a may be performed while the mask pattern MP is formed on the first preliminary semiconductor pattern SP1a. The mask pattern MP may be removed after forming the second preliminary semiconductor pattern SP2a.

The second preliminary semiconductor pattern SP2a may include an oxide semiconductor. For example, the second preliminary semiconductor pattern SP2a may include InₓGa_{y}Zn_{z}O, InₓGa_{y}Si_{z}O, InₓSn_{y}Zn_{z}O, InₓZn_{y}O, ZnₓO, ZnₓSn_{y}O, ZnₓO_{y}N, ZrₓZn_{y}Sn_{z}O, SnₓO, HfₓIn_{y}Zn_{z}O, GaₓZn_{y}Sn_{z}O, AlₓZn_{y}Sn_{z}O, YbₓGa_{y}Zn_{z}O, and/or InₓGa_{y}O. As example embodiments, the second preliminary semiconductor pattern SP2a may include Indium Gallium Zinc Oxide (IGZO). The second preliminary semiconductor pattern SP2a may include a single layer or multiple layers of an oxide semiconductor. The second preliminary semiconductor pattern SP2a may include an amorphous, crystalline, or polycrystalline oxide semiconductor. In example embodiments, the second preliminary semiconductor pattern SP2a may include a two-dimensional semiconductor material. For example, the 2D semiconductor material may include graphene, carbon nanotubes, or a combination thereof. The second preliminary semiconductor pattern SP1a may have a second conductivity type. For example, the conductivity type of the second preliminary semiconductor pattern SP2a may be n-type.

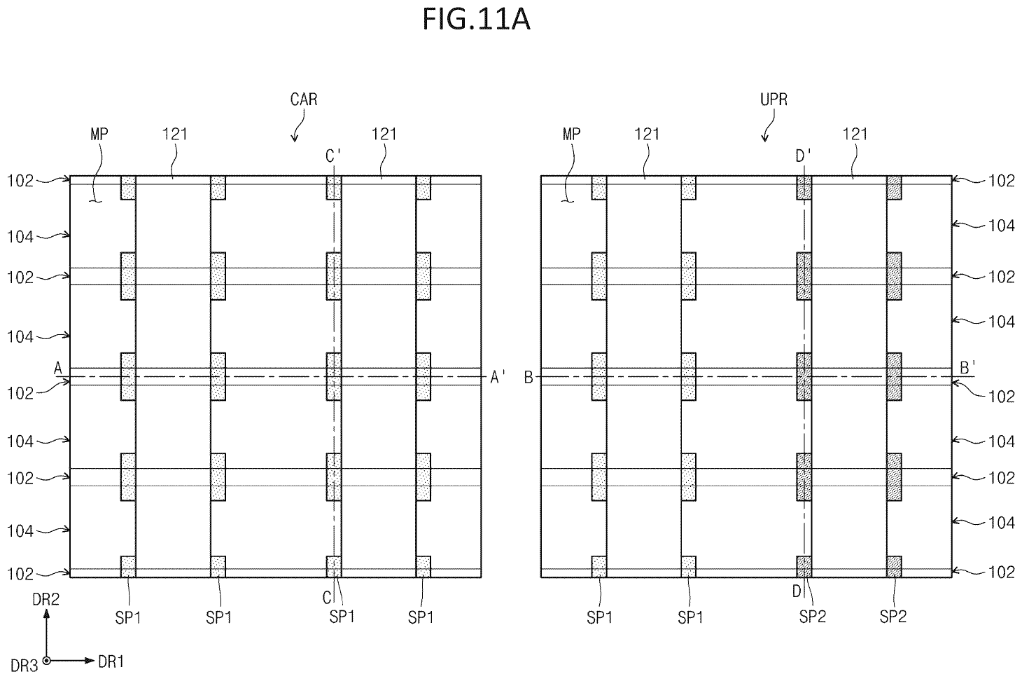

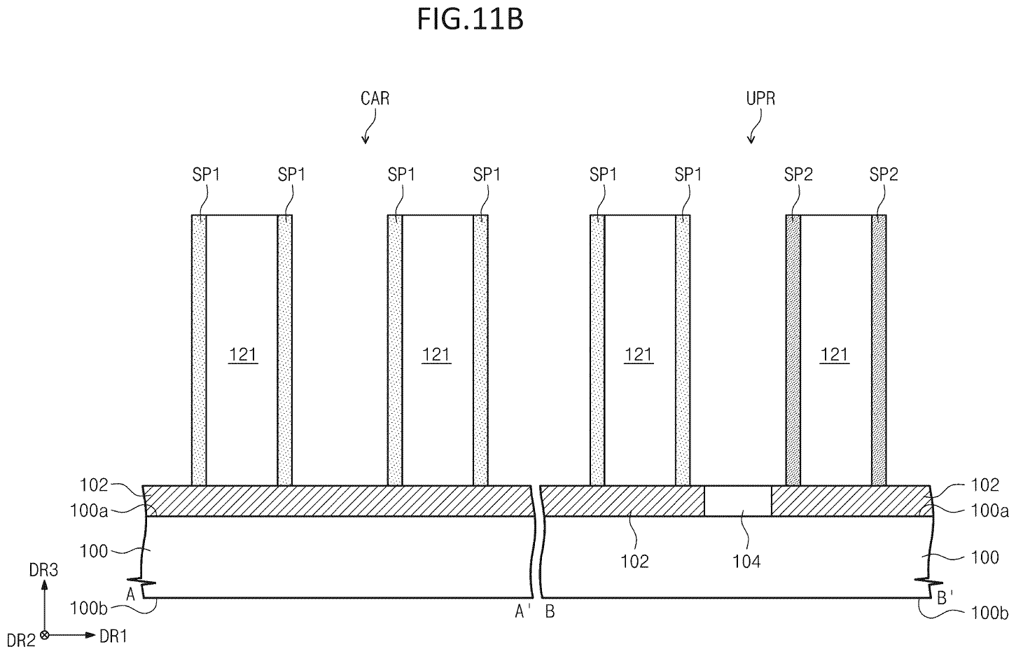

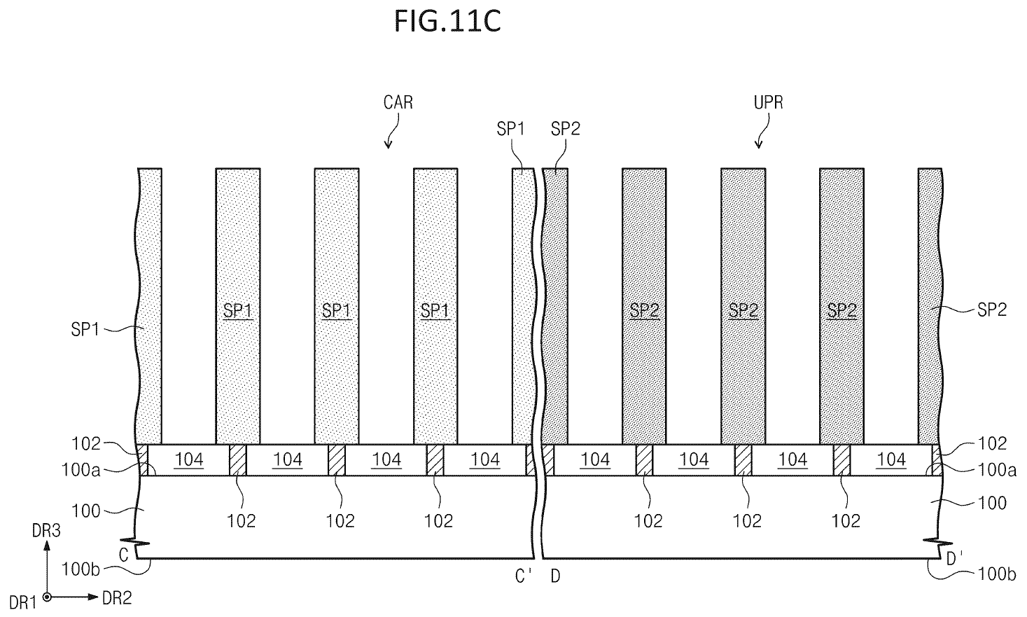

Referring to FIGS. 7, 11A, 11B, and 11C, first semiconductor patterns SP1 and second semiconductor patterns SP2 may be disposed on the first conductive lines 102 (S104).

First semiconductor patterns SP1 may be provided on side surfaces of the preliminary gate insulating layers 121. The first semiconductor patterns SP1 may be arranged along the second direction DR2 on the side surfaces of the preliminary gate insulating layers 121. For example, on one side of the preliminary gate insulating layers 121, the first semiconductor patterns SP1 may be arranged at regular intervals along the second direction DR2. The first semiconductor patterns SP1 may be arranged along the first conductive lines 102. For example, the first semiconductor patterns SP1 may be arranged along the first direction DR1. In example embodiments, a pair of first semiconductor patterns SP1 immediately adjacent to each other may be spaced apart along the first direction DR1 with the preliminary gate insulating layer 121 interposed therebetween. One of the pair of first semiconductor patterns SP1 immediately adjacent to each other may be disposed on one side of the preliminary gate insulating layer 121, and the other may be disposed on the other side of the preliminary gate insulating layer 121.

Second semiconductor patterns SP2 may be provided on side surfaces of the preliminary gate insulating layers 121. The second semiconductor patterns SP2 may be arranged along the second direction DR2 on the side surfaces of the preliminary gate insulating layers 121. For example, on one side of the preliminary gate insulating layers 121, the second semiconductor patterns SP2 may be arranged at regular intervals along the second direction DR2. The second semiconductor patterns SP2 may be arranged along the first conductive lines 102. For example, the second semiconductor patterns SP2 may be arranged along the first direction DR1. In example embodiments, a pair of second semiconductor patterns SP2 immediately adjacent to each other may be spaced apart along the first direction DR1 with the preliminary gate insulating layer 121 interposed therebetween. One of the pair of second semiconductor patterns SP2 immediately adjacent to each other may be disposed on one side of the preliminary gate insulating layer 121, and the other one may be disposed on the other side of the preliminary gate insulating layer 121.

The first semiconductor patterns SP1 and the second semiconductor patterns SP2 may be formed by patterning the first preliminary semiconductor pattern SP1a and the second preliminary semiconductor pattern SP2a. The first preliminary semiconductor pattern SP1a and the second preliminary semiconductor pattern SP2a are patterned to form the top and side surfaces of the preliminary gate insulating layers 121, the top surfaces of the first conductive lines 102, and the top surfaces the lower insulator layer 104 may be exposed.

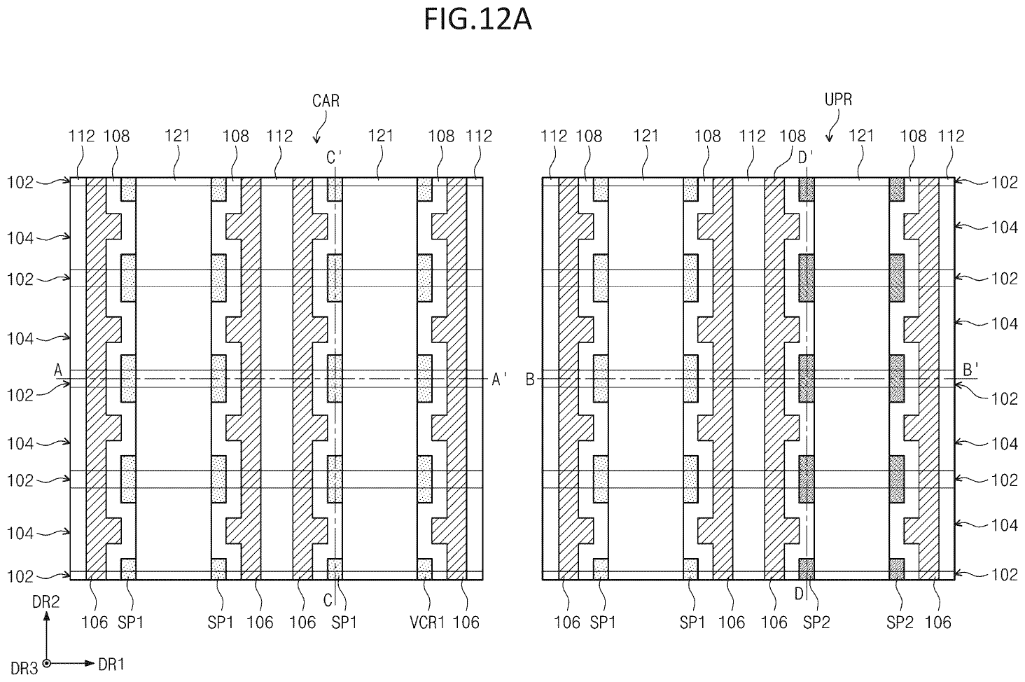

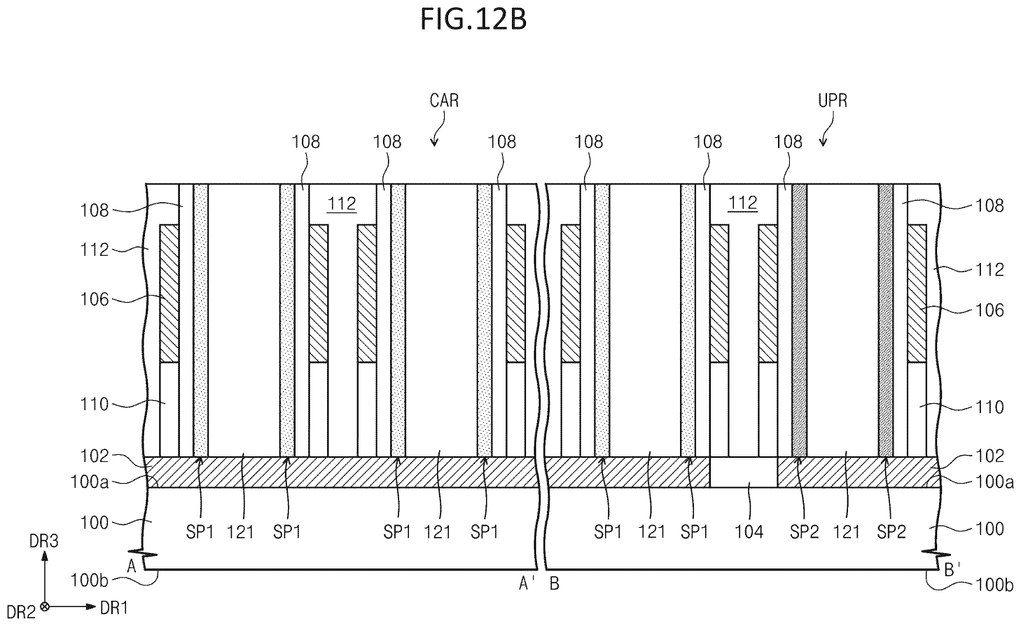

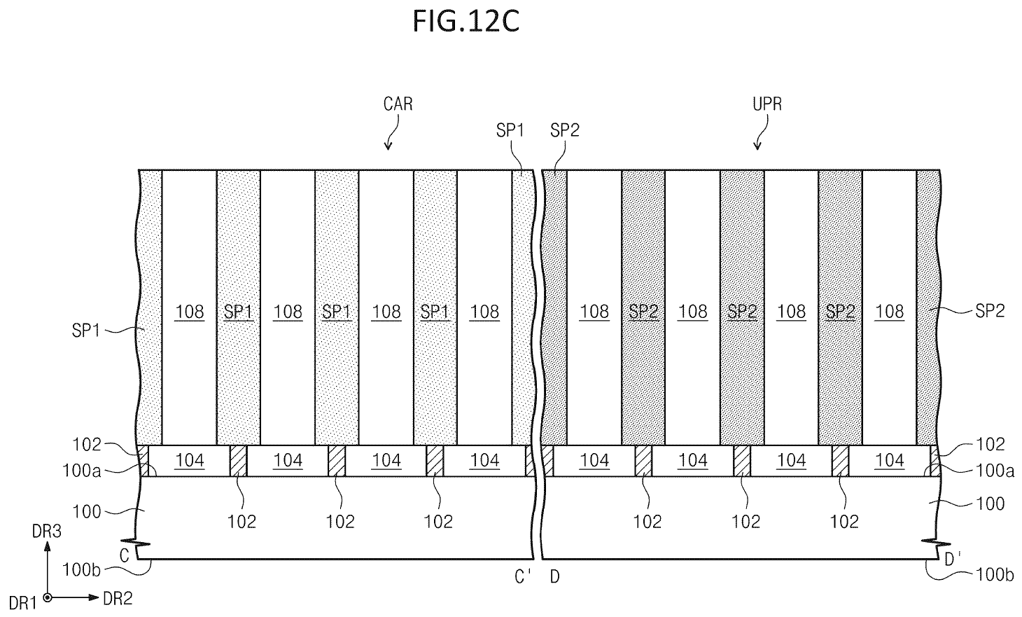

Referring to FIGS. 7, 12A, 12B, and 12C, a first gate insulating layers 108, second conductive lines 106, first insulating patterns 110, and second insulating patterns 112 may be disposed on side surfaces of the first semiconductor patterns SP1, the second semiconductor patterns SP2, and the preliminary gate insulating layers 121 (S105). The first gate insulating layers 108 may extend along side surfaces of the first semiconductor patterns SP1, the second semiconductor patterns SP2, and the preliminary gate insulating layers 121. For example, the first gate insulating layers 108 may be disposed along the profiles of side surfaces of the first semiconductor patterns SP1, the second semiconductor patterns SP2, and the preliminary gate insulating layers 121. The first gate insulating layers 108 may be arranged along the first direction DR1. The first gate insulating layer 108 may include a low-k dielectric, silicon oxide, and/or a high-k dielectric. The high dielectric material may be a metal oxide or metal oxynitride. For example, the first gate insulating layer 108 may include HfO₂, HfSiO, HfSiON, HfTaO, HfTiO, HfZrO, ZrO₂, Al₂O₃, or a combination thereof. For example, the first gate insulating layers 108 may be formed using physical vapor deposition (PVD), thermal chemical vapor deposition (thermal CVD), low pressure chemical vapor deposition (LP-CVD), plasma enhanced chemical vapor deposition (PE-CVD), and/or atomic layer deposition (ALD).

Second conductive lines 106 may be disposed on the first gate insulating layers 108. The second conductive lines 106 may be spaced apart from the preliminary gate insulating layers 121 with the first gate insulating layers 108 interposed therebetween. The second conductive lines 106 may extend along the first gate insulating layers 108. For example, the second conductive lines 106 may extend along the second direction DR2. The second conductive lines 106 may be arranged along the first direction DR1. The second conductive lines 106 may include an electrically conductive material. For example, the second conductive lines 106 may include doped polysilicon, metal (e.g., Al, Cu, Ti, Ta, Ru, W, Mo, Pt, Ni, Co), conductive metal nitrides (e.g. TiN, TaN, WN, NbN, TiAlN, TiSiN, TaSiN, RuTiN), conductive metal silicides, and/or conductive metal oxides (e.g. PtO, RuO₂, IrO₂, SRO(SrRuO₃), BSRO((Ba,Sr) RuO₃), CRO(CaRuO₃), LSCo). The second conductive lines 106 may have a single-layer or multi-layer structure. In some embodiments, the second conductive lines 106 may include a two-dimensional semiconductor material. For example, the 2D semiconductor material may include graphene, carbon nanotubes, or a combination thereof. The second conductive lines 106 may be formed by depositing an electrically conductive layer on a side of the first gate insulating layer 108 and performing an anisotropic etching process on the deposited electrically conductive layer. For example, depositing an electrically conductive layer may be performed by chemical vapor deposition (CVD), physical vapor deposition (PVD), or atomic layer deposition (ALD). The second conductive lines 106 may be spaced apart from the first conductive line 102 and the lower insulating layers 104.

First insulating patterns 110 may be disposed on bottom surfaces of the second conductive lines 106. The first insulating patterns 110 may extend along bottom surfaces of the second conductive lines 106. For example, the first insulating patterns 110 may extend along the second direction DR2. The first insulating patterns 110 may at least partially overlap the second conductive lines 106 and the third direction DR3. The first insulating patterns 110 may be disposed between the second conductive lines 106 and the first conductive lines 102 and between the second conductive lines 106 and the lower insulating layers 104. For example, the first insulating patterns 110 may be formed by depositing an insulating layer on the side of the first gate insulating layer 108 located below the second conductive lines 106 and performing an anisotropic etching process on the deposited insulating layer. For example, depositing an insulating layer may be performed by chemical vapor deposition (CVD), physical vapor deposition (PVD), or atomic layer deposition (ALD). The first insulating patterns 110 may include an insulating material. For example, the first insulating patterns 110 may include silicon oxide, silicon nitride, and/or silicon oxynitride.

Second insulating patterns 112 may be disposed between the first gate insulating layers 108. The second insulating patterns 112 may at least partially cover the second conductive lines 106 and the first insulating patterns 110. The second insulating patterns 112 may at least partially fill the region between the first gate insulating layers 108. The second insulating patterns 112 may include an insulating material. For example, the second insulating patterns 112 may include silicon oxide, silicon nitride, and/or silicon oxynitride. In example embodiments, the second insulating patterns 112 may be formed by depositing an insulating layer between the preliminary gate insulating layers 121. For example, depositing an insulating layer may be performed by chemical vapor deposition (CVD), physical vapor deposition (PVD), and/or atomic layer deposition (ALD).

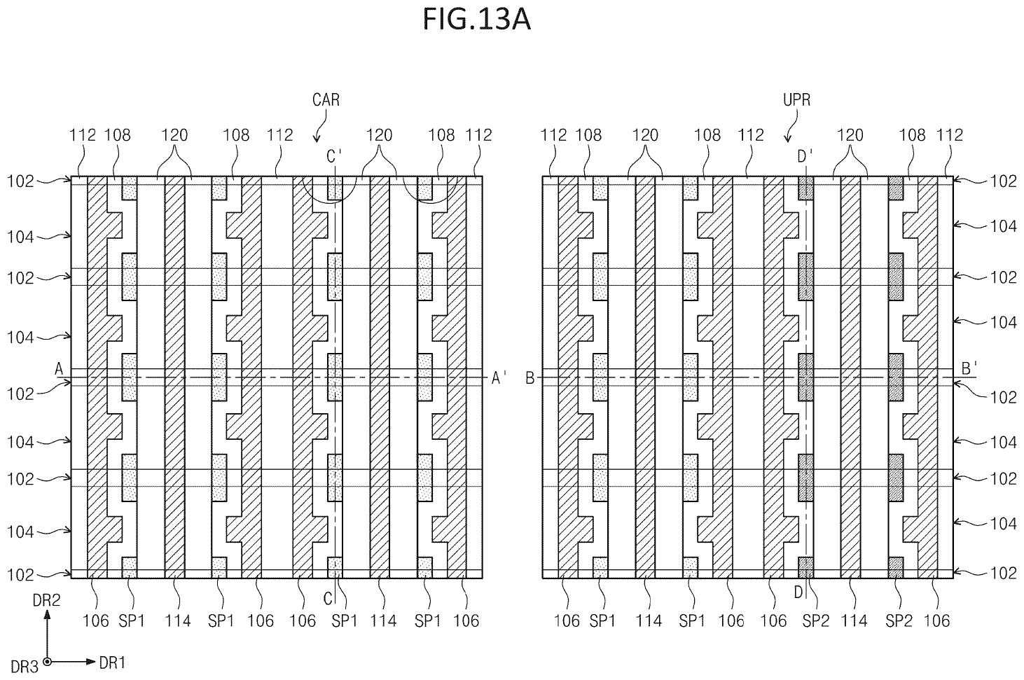

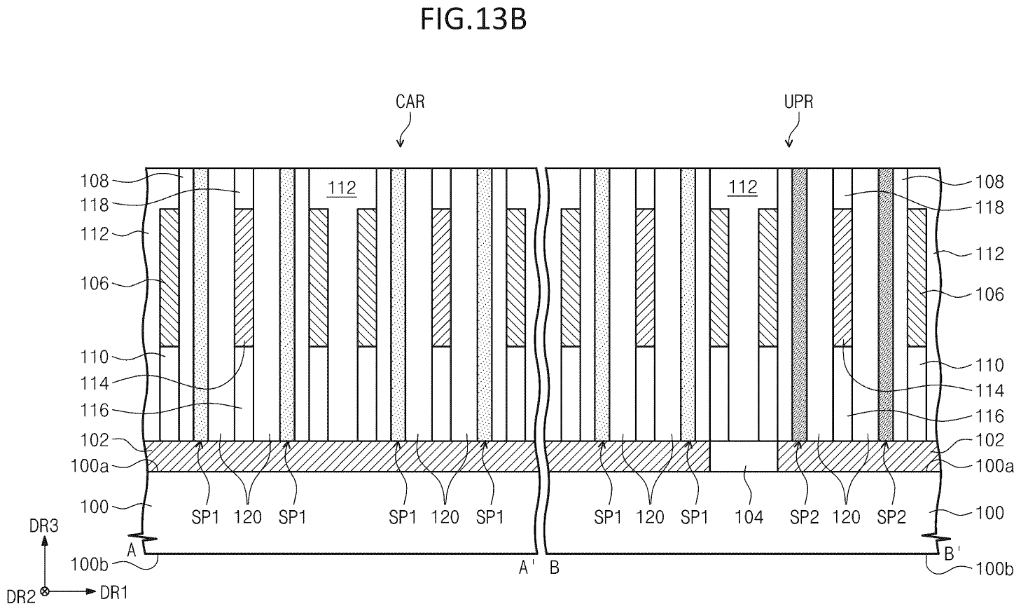

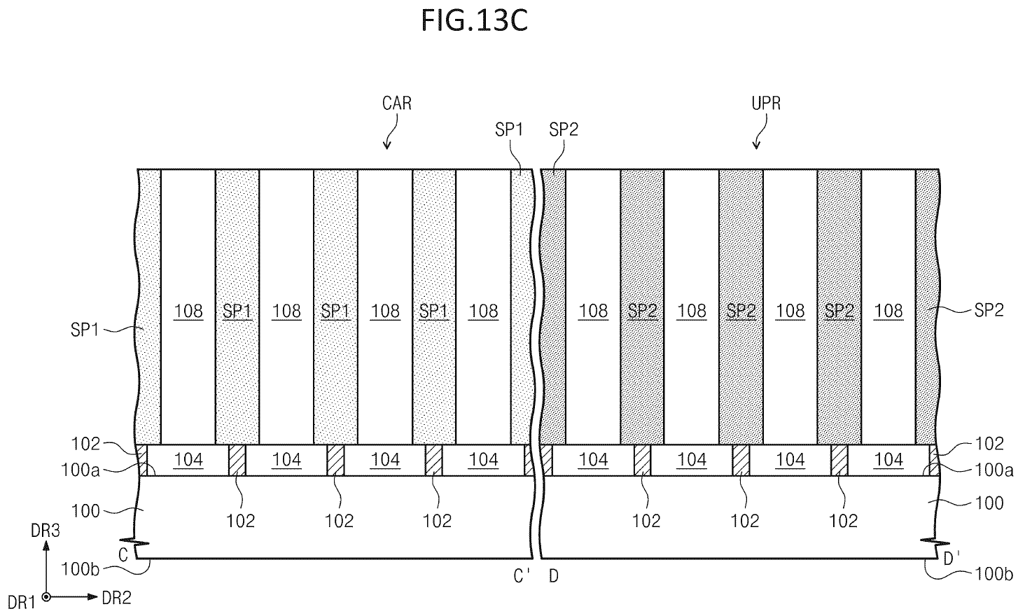

Referring to FIGS. 7, 13A, 13B, and 13C, third insulating patterns 116, third conductive lines 114, and fourth insulating patterns 118 may be disposed (S106).

Forming the third insulating patterns 116, the third conductive lines 114, and the fourth insulating patterns 118 may include forming trenches 121t penetrating the preliminary gate insulating layers 121 along the third direction DR3 and sequentially forming the third insulating pattern 116, the third conductive line 114, and the fourth insulating pattern 118 in each of the trenches 121t. Trenches 121t may be disposed in the preliminary gate insulating layer 121 to form the second gate insulating layer 120. The third insulating pattern 116, third conductive line 114, and fourth insulating pattern 118 may extend along the second conductive lines 106. For example, the third insulating pattern 116, the third conductive line 114, and the fourth insulating pattern 118 may extend along the second direction DR2. The third insulating patterns 116 and fourth insulating patterns 118 may include an insulating material. For example, the third insulating patterns 116 and fourth insulating patterns 118 may include silicon oxide, silicon nitride, and/or silicon oxynitride.

The third conductive lines 114 may include an electrically conductive material. For example, the third conductive lines 114 may include doped polysilicon, metal, conductive metal nitride, metal-semiconductor compound, conductive metal oxide, graphene, carbon nanotube, and/or a combination thereof. For example, the back gate electrode 44 may include doped polysilicon, Al, Cu, Ti, Ta, Ru, W, Mo, Pt, Ni, Co, TiN, TaN, WN, NON, TiAl, TiAlN, TiAlC, TaAlC, TiSi, TiSiN, TaSi, TaSiN, RuTiN, NiSi, CoSi, IrOx, RuOx, graphene, carbon nanotube, or a combination thereof. The third conductive lines 114 may have a single-layer or multi-layer structure.

The third conductive lines 114 may be back gate electrodes of the vertical cell transistors VCT in FIG. 5B, the first vertical peripheral transistors VPT1 in FIG. 5B, and the second vertical peripheral transistors VPT2 in FIG. 5B. The third conductive lines 114 may raise the threshold voltages of the vertical cell transistors VCT in FIG. 5B, the first vertical peripheral transistors VPT1 in FIG. 5B, and the second vertical peripheral transistors VPT2 in FIG. 5B. Accordingly, even if the vertical cell transistors VCT in FIG. 5B, the first vertical peripheral transistors VPT1 in FIG. 5B, and the second vertical peripheral transistors VPT2 in FIG. 5B have small sizes, the threshold voltage can be reduced and the leakage current characteristics may be prevented from being deteriorated.

Referring to FIGS. 7, 5A, 5B, and 5C, the upper insulating layer 132, first pads 130, second pads 131, storage electrode 142, capacitor dielectric layer 144, the upper electrode 146, and the capping layer 150 may be disposed (S107). The upper insulating layer 132 may be disposed on the fourth insulating patterns 118. For example, the upper insulating layer 132 may be formed by depositing an insulating layer extending along the first direction DR1 and the second direction DR2 on the fourth insulating patterns 118 and patterning the insulating layer. For example, the deposition process may be chemical vapor deposition (CVD), physical vapor deposition (PVD), or atomic layer deposition (ALD). Pad holes 132h in which the pads 130 are disposed may be formed by patterning the insulating layer. Pad holes 132h may be disposed on the first semiconductor patterns SP1 and the second semiconductor patterns SP2, respectively. The pad holes 132h may expose the first semiconductor patterns SP1 and the second semiconductor patterns SP2. The upper insulating layer 132 may include an insulating material. For example, the upper insulating layer 132 may include silicon oxide, silicon nitride, or silicon oxynitride.

The first pads 130 may be disposed in each of the pad holes 132h of the cell array region CAR. Accordingly, the first pads 130 may be disposed on the first semiconductor patterns SP1, respectively. The first pads 130 may at least partially vertically overlap the first semiconductor patterns SP1. For example, the first pads 130 may be formed by depositing an electrically conductive material into the pad holes 132h of the cell array region CAR. For example, the deposition process may be chemical vapor deposition (CVD), physical vapor deposition (PVD), or atomic layer deposition (ALD). The first pads 130 may be electrically connected to the first semiconductor patterns SP1. The first pads 130 may include an electrically conductive material. For example, the pads 130 may include doped polysilicon, conductive metal nitride, conductive metal silicon nitride, metal carbonitride, conductive metal silicide, conductive metal oxide, two-dimensional material, metal, and/or a metal alloy.

The second pads 131 may be disposed in the pad holes 132h of the upper peripheral region UPR, respectively. Accordingly, the second pads 131 may be disposed on the first semiconductor patterns SP1 and the second semiconductor patterns SP2 in the upper peripheral region UPR, respectively. The second pads 131 may at least partially vertically overlap the first semiconductor patterns SP1 and the second semiconductor patterns SP2. For example, the second pads 131 may be formed by depositing an electrically conductive material into the pad holes 132h of the upper peripheral region UPR. For example, the deposition process may be chemical vapor deposition (CVD), physical vapor deposition (PVD), or atomic layer deposition (ALD). The second pads 131 may be electrically connected to the first semiconductor patterns SP1 and the second semiconductor patterns SP2. The second pads 131 may include an electrically conductive material. For example, the second pads 131 may include doped polysilicon, conductive metal nitride, conductive metal silicon nitride, metal carbonitride, conductive metal silicide, conductive metal oxide, two-dimensional material, metal, and/or metal alloy.

The lower electrodes 142, the capacitor dielectric layer 144, and the upper electrode 146 may be disposed in the cell array region CAR. The lower electrodes 142, the capacitor dielectric layer 144, and the upper electrode 146 may form capacitors. The lower electrodes 142 may be arranged in a matrix form along the first direction DR1 and the second direction DR2. The lower electrodes 142 may completely or partially overlap the first pads 130 in the third direction DR3. The lower electrodes 142 may contact the first pads 130. From a two-dimensional perspective, the lower electrodes 142 may have various shapes, such as circular, oval, rectangular, square, diamond, or hexagonal shapes. The lower electrodes 142 may include an electrically conductive material. The lower electrodes 142 may include, for example, a conductive semiconductor material, conductive metal nitride, conductive metal silicon nitride, metal carbonitride, conductive metal silicide, conductive metal oxide, and/or metal.

The capacitor dielectric layer 144 may be disposed on the surfaces of the lower electrodes 142 and the upper surface of the upper insulating layer 132. For example, the capacitor dielectric layer 144 may extend along the surfaces of the lower electrodes 142 and the upper surface of the upper insulating layer 132. The capacitor dielectric layer 144 may include a ferroelectric material, an antiferroelectric material, and/or a paraelectric material. For example, the capacitor dielectric layer 144 may include one of a ferroelectric material, an antiferroelectric material, a paraelectric material, a combination of a ferroelectric material and an antiferroelectric material, a combination of a ferroelectric material and a paraelectric material, a combination of a paraelectric material and an antiferroelectric material, and a combination of a ferroelectric material, antiferroelectric materials, and paraelectric materials.

The upper electrode 146 may be disposed on the capacitor dielectric layer 144. The upper electrode 146 may be spaced apart from the lower electrodes 142 by the capacitor dielectric layer 144. The upper electrode 146 may include an electrically conductive material. The upper electrode 146 may include, for example, a conductive semiconductor material, conductive metal nitride, conductive metal silicon nitride, metal carbonitride, conductive metal silicide, conductive metal oxide, and/or metal.

The capping layer 150 may be disposed in the upper peripheral region UPR. The upper peripheral region UPR might not include a capacitor. The capping layer 150 may be disposed on the second pads 131 and the upper insulating layer 132. For example, the capping layer 150 may be formed by depositing an insulating material on the second pads 131 and the upper insulating layer 132. For example, the deposition process may be chemical vapor deposition (CVD), physical vapor deposition (PVD), or atomic layer deposition (ALD). For example, the capping layer 150 may include silicon oxide, silicon nitride, or silicon oxynitride. A capping layer 150 may be disposed in the upper peripheral region UPR. Vertical conductive lines VCL and horizontal conductive lines HCL that provide electrical connections between the second pads 131 and other components may be disposed in the capping layer 150.

In an example, instead of a capacitor, a variable resistance pattern may be disposed that may be switched between two resistance states by electrical pulses. For example, variable resistance patterns may include phase-change materials whose crystal state changes depending on the amount of current, perovskite compounds, transition metal oxides, magnetic materials, ferromagnetic materials, or antiferromagnetic materials.

At least some of the peripheral circuits of the present invention may be disposed in the cell array structure CS. In example embodiments, a method of manufacturing a semiconductor memory device 10 with increased integration or reduced size may be provided.

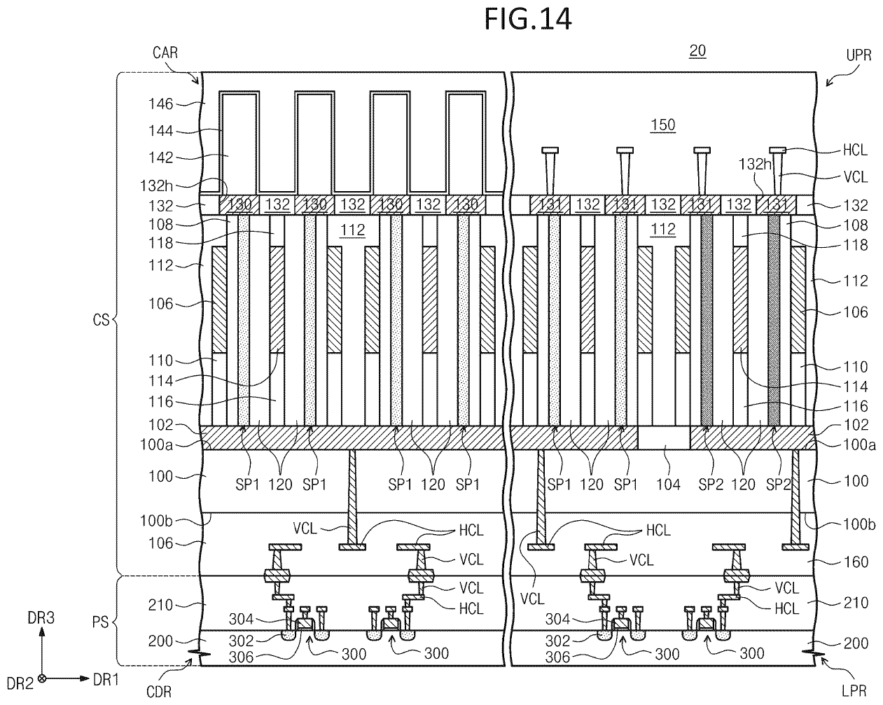

FIG. 14 is a cross-sectional view of a semiconductor memory device according to example embodiments. To the extent that elements are not described in detail with respect to this figure, it may be assumed that these elements are at least similar to corresponding elements that have been shown and described with respect to FIGS. 5A to 5C.

Referring to FIG. 14, a peripheral circuit structure PS and a cell array structure CS may be provided. The cell array structure CS may be provided on the peripheral circuit structure PS. The peripheral circuit structure PS and the cell array structure CS may be arranged along the third direction DR3. Unlike what is described with reference to FIGS. 5A to 5C, the cell array structure CS may further include a lower capping layer 160 provided on the second side 100b of the substrate 100, vertical conductive lines VCL, and horizontal conductive lines HCL. The lower capping layer 160 may at least partially cover the second surface 100b of the substrate 100. The lower capping layer 160 may include an insulating material. For example, the lower capping layer 160 may include silicon oxide, silicon nitride, or silicon oxynitride. In example embodiments, the lower capping layer 160 may have a multilayer structure in which a plurality of insulating layers are stacked.

Vertical conductive lines VCL and horizontal conductive lines HCL may be configured to provide electrical connections between different components. The configurations of the vertical conductive lines VCL and horizontal conductive lines HCL shown in FIG. 14 are for the purposes of providing an example. The configuration of vertical conductive lines VCL and horizontal conductive lines HCL may be determined as needed.

The peripheral circuit structure PS may include a peripheral substrate 200, horizontal peripheral transistors 300, a peripheral insulating layer 210, vertical conductive lines VCL, and horizontal conductive lines HCL. A peripheral substrate 200 may be provided. The peripheral substrate 200 may be disposed in the cell driving region CDR and the lower peripheral region (LPR). The peripheral substrate 200 may include a semiconductor material. For example, the peripheral substrate 200 may include silicon (Si), germanium (Ge), and/or silicon-germanium (SiGe). The peripheral substrate 200 may have a first conductivity type. For example, the first conductivity type may be p-type or n-type. When the conductivity type of the peripheral substrate 200 is p-type, the peripheral substrate 200 may be a silicon (Si) substrate containing Group 3 elements (e.g., boron (B), aluminum (Al), gallium (Ga), indium (In), etc.) or Group 2 elements as impurities. When the conductivity type of the peripheral substrate 200 is n-type, the peripheral substrate 200 may be a silicon (Si) substrate containing Group 5 elements (e.g., phosphorus (P), arsenic (As), antimony (Sb), etc.), group 6, or group 7 elements as impurities. When the first conductivity type is p-type or n-type, the second conductivity type may be n-type or p-type, respectively. The peripheral substrate 200 may be an epi layer formed through an epitaxial growth process.

The horizontal peripheral transistors 300 may include planar type transistors. Each of the horizontal peripheral transistors 300 may have a channel extending along a direction parallel to the top surface of the peripheral substrate 200 (e.g., first direction DR1). Source/drain regions 302 of the horizontal peripheral transistors 300 may be provided on the peripheral substrate 200. Channels of horizontal peripheral transistors 300 may be provided between source/drain regions 302. Gate electrodes 304 of the horizontal peripheral transistors 300 may be provided on the upper surface of the peripheral substrate 200. Gate insulating layers 306 of the horizontal peripheral transistors 300 may be provided between the gate electrodes 304 of the horizontal peripheral transistors 300 and the second front surface 202a. When viewed along the third direction DR3, the source/drain regions 302 may be spaced apart from each other with the gate electrodes 304 interposed therebetween. Although the source/drain regions 302 are shown to be spaced apart from each other along the first direction DR1, this is merely illustrative. The separation direction of the source/drain regions 302 may be determined according to the shape of the horizontal peripheral transistor 300.

The peripheral insulating layer 210 may be provided on the peripheral substrate 200. The peripheral insulating layer 210 may at least partially cover the horizontal peripheral transistors 300. The peripheral insulating layer 210 may include an insulating material. For example, the peripheral insulating layer 210 may include silicon oxide, silicon nitride, and/or silicon oxynitride. In example embodiments, the peripheral insulating layer 210 may have a multilayer structure in which a plurality of insulating layers are stacked.

Vertical conductive lines VCL and horizontal conductive lines HCL may be configured to provide electrical connections between different components. The configurations of the vertical conductive lines VCL and horizontal conductive lines HCL shown in FIG. 14 are for the purposes of providing an example. The configuration of vertical conductive lines VCL and horizontal conductive lines HCL may be determined as needed. For example, vertical conductive lines VCL and horizontal conductive lines HCL may be provided between the upper electrode 146 and the horizontal peripheral transistors 300 to provide electrical connection.

Although the horizontal peripheral transistors 300 are shown as being provided in the cell driving region CDR and the lower peripheral region (LPR), this is merely example embodiments. In an example, the horizontal peripheral transistors 300 may be provided in the cell driving region CDR rather than in the lower peripheral region LPR.

At least some of the peripheral circuits of the present invention may be disposed in the cell array structure CS. In example embodiments, the integration degree of the semiconductor memory device 20 may be increased. In example embodiments, the size of the semiconductor memory device 20 may be reduced.

According to the present disclosure, the present invention may provide a semiconductor memory device with increased integration.

According to the present disclosure, the present invention may provide a semiconductor memory device having a reduced size.

While the present disclosure is described with reference to embodiments thereof, it will be apparent to those of ordinary skill in the art that various changes and modifications may be made thereto without departing from the spirit and scope of the present disclosure.

What is claimed is:

1. A semiconductor memory device, comprising:
a peripheral circuit structure; and
a cell array structure disposed on the peripheral circuit structure and including a plurality of cell array regions and an upper peripheral region disposed between cell regions of the plurality of cell array regions,
wherein the cell array structure includes vertical cell transistors, first vertical peripheral transistors, and second vertical peripheral transistors,
wherein each of the vertical cell transistors, the first vertical peripheral transistors, and the second vertical peripheral transistors includes a channel extending along a third direction parallel to an arrangement direction of the peripheral circuit structure and the cell array structure,
wherein the vertical cell transistors are disposed in the cell array region and have a first polarity,
wherein the first vertical peripheral transistors are disposed in the upper peripheral region and have the first polarity, and
wherein the second vertical peripheral transistors are disposed in the upper peripheral region and have a second polarity different from the first polarity.

2. The semiconductor memory device of claim 1, wherein each of the vertical cell transistors and the first vertical peripheral transistors includes a first semiconductor pattern extending along the third direction and having a first conductivity type and a first gate electrode facing the first semiconductor pattern, and
wherein each of the second vertical peripheral transistors includes a second semiconductor pattern extending along the third direction and having a second conductivity type, different from the first conductivity type, and a second gate electrode facing the second semiconductor pattern.

3. The semiconductor memory device of claim 2, wherein the cell array structure further includes first conductive lines extending along the first direction, and
wherein the first semiconductor patterns and the second semiconductor patterns are disposed on the first conductive lines.

4. The semiconductor memory device of claim 3, wherein, in the cell array region, the first semiconductor patterns arranged along the first direction are electrically connected to one of the first conductive lines.

5. The semiconductor memory device of claim 3, wherein, in the upper peripheral region, the first semiconductor pattern and the second semiconductor pattern that are immediately adjacent to each other along the first direction are electrically connected to different first conductive lines.

6. The semiconductor memory device of claim 3, wherein, in the upper peripheral region, first semiconductor patterns that are immediately adjacent to each other along the first direction are electrically connected to different first conductive lines.

7. The semiconductor memory device of claim 2, wherein the cell array region and the upper peripheral region further include second conductive lines arranged along the first direction and extending along the second direction, and
wherein the second conductive lines face the first semiconductor patterns and the second semiconductor patterns, and include the first gate electrodes and the second gate electrodes.

8. The semiconductor memory device of claim 7, wherein the cell array region and the upper peripheral region further include third conductive lines arranged along the first direction and extending along the second direction, and
wherein the third conductive lines are disposed in regions between a pair of vertical cell transistors immediately adjacent to each other, between a pair of first vertical peripheral transistors immediately adjacent to each other, and between a pair of second vertical peripheral transistors directly adjacent to each other.

9. The semiconductor memory device of claim 8, wherein the third conductive lines are configured to apply a back gate voltage that adjusts a threshold voltage to the vertical cell transistors, the first vertical peripheral transistors, and the second vertical peripheral transistors, and
wherein each of a pair of vertical cell transistors immediately adjacent to each other, a pair of first vertical peripheral transistors directly adjacent to each other, and a pair of second vertical peripheral transistors directly adjacent to each other shares one of the third conductive lines.

10. The semiconductor memory device of claim 1, wherein the cell array structure further includes:
first pads disposed on the vertical cell transistors, respectively;
capacitors disposed on the first pads, respectively; and
second pads electrically connected to the first vertical peripheral transistors and the second vertical peripheral transistors,
wherein, in a plan view, the capacitors at least partially overlap the vertical cell transistors and are spaced apart from the first vertical peripheral transistors and the second vertical peripheral transistors.

11. The semiconductor memory device of claim 10, wherein, first vertical peripheral transistor and second vertical peripheral transistor that are immediately adjacent to each other are electrically connected to each other by one of the second pads.

12. The semiconductor memory device of claim 10, wherein, first vertical peripheral transistors immediately adjacent to each other are electrically connected to each other by one of the second pads.

13. The semiconductor memory device of claim 12, wherein vertical cell transistor and the capacitor immediately adjacent to each other are electrically connected to each other by a first pad disposed between the vertical cell transistor and the capacitor directly adjacent to each other.

14. The semiconductor memory device of claim 10, wherein the cell array structure further includes vertical conductive lines and horizontal conductive lines electrically connected to the second pads.

15. The semiconductor memory device of claim 1, wherein the first vertical peripheral transistors and the second vertical peripheral transistors are disposed in a region of the upper peripheral region arranged in the first direction from the cell array region.

16. A semiconductor memory device, comprising:
a peripheral circuit structure; and
a cell array structure disposed on the peripheral circuit structure;
wherein the peripheral circuit structure includes horizontal peripheral transistors having a channel extending along a first direction intersecting an arrangement direction of the peripheral circuit structure and the cell array structure,
wherein the cell array structure includes capacitors, vertical cell transistors, first vertical peripheral transistors, and second vertical peripheral transistors,
wherein the capacitors are electrically connected to the vertical cell transistors,
wherein each of the vertical cell transistors, the first vertical peripheral transistors, and the second vertical peripheral transistors has a channel extending along a third direction parallel to an arrangement direction of the peripheral circuit structure and the cell array structure, and
wherein the first vertical peripheral transistors and the second vertical peripheral transistors have a first polarity and a second polarity different from the first polarity, respectively.

17. The semiconductor memory device of claim 16, wherein the peripheral circuit structure and the cell array structure further include vertical conductive lines and horizontal conductive lines disposed between the capacitors and the horizontal peripheral transistors, and
wherein the capacitors and the horizontal peripheral transistors are electrically connected to each other by the vertical conductive lines and the horizontal conductive lines.

18. The semiconductor memory device of claim 16, wherein the cell array structure includes a plurality of cell array regions and an upper peripheral region disposed between the plurality of cell array regions,
wherein the vertical cell transistors and the capacitors are disposed in the plurality of cell array regions,
wherein the first vertical peripheral transistors and the second vertical peripheral transistors are disposed in the upper peripheral region, and
wherein, in a plan view, the horizontal peripheral transistors are disposed in regions that at least partially overlap the plurality of cell array regions.

19. A semiconductor memory device, comprising:
a substrate including a plurality of cell array regions and an upper peripheral region disposed between the plurality of cell array regions;
first conductive lines extending along a first direction on the substrate and arranged along a second direction intersecting the first direction;
vertical cell transistors, first vertical peripheral transistors, and second vertical peripheral transistors disposed on the first conductive lines; and
capacitors disposed on each of the vertical cell transistors,
wherein each of the vertical cell transistors, the first vertical peripheral transistors, and the second vertical peripheral transistors has a channel extending along a third direction perpendicular to the top surface of the substrate,
wherein the vertical cell transistors are N-type metal-oxide-semiconductor (NMOS) transistors disposed in the cell array region,
wherein the first vertical peripheral transistors are NMOS transistors disposed in the upper peripheral region, and
wherein the second vertical peripheral transistors are P-type metal-oxide-semiconductor (PMOS) transistors disposed in the upper peripheral region.

20. The semiconductor memory device of claim 19, further comprising:
second conductive lines arranged along the first direction on the substrate and extending along the second direction; and
third conductive lines disposed in regions between a pair of vertical cell transistors that are immediately adjacent to each other among the vertical cell transistors, between a pair of first vertical peripheral transistors that are immediately adjacent to each other among the first vertical peripheral transistors, and between a pair of second vertical peripheral transistors that are immediately adjacent to each other among the second vertical peripheral transistors,
wherein the second conductive lines are configured to apply gate voltages to the vertical cell transistors, the first vertical peripheral transistors, and the second vertical peripheral transistors, wherein the third conductive lines are configured to apply back gate voltages that adjust threshold voltages to the vertical cell transistors, the first vertical peripheral transistors, and the second vertical peripheral transistors.
